(19) United States
(12) Patent Application Publication
(10) Pub. No.: US 2024/0329286 A1
(43) Pub. Date: Oct. 3, 2024

(54) LIGHT ABSORPTION FILTER, OPTICAL FILTER, MANUFACTURING METHOD FOR OPTICAL FILTER, ORGANIC ELECTROLUMINESCENT DISPLAY DEVICE, INORGANIC ELECTROLUMINESCENT DISPLAY DEVICE, AND LIQUID CRYSTAL DISPLAY DEVICE

(71) Applicant: FUJIFILM Corporation, Tokyo (JP)

(72) Inventors: Nobutaka FUKAGAWA, Kanagawa (JP); Yu NAITO, Kanagawa (JP)

(73) Assignee: FUJIFILM Corporation, Tokyo (JP)

(21) Appl. No.: 18/743,785

(22) Filed: Jun. 14, 2024

Related U.S. Application Data
(63) Continuation of application No. PCT/JP2023/007138, filed on Feb. 27, 2023.

(30) Foreign Application Priority Data
Feb. 28, 2022 (JP) 2022-029959

(51) Int. Cl. G02B 5/22

(52) U.S. Cl. CPC G02B 5/22

(57) ABSTRACT

A light absorption filter that includes a wavelength selective absorption layer containing a resin and a squarine-based coloring agent represented by General Formula (1) and includes an adjacent layer arranged on at least one surface of the wavelength selective absorption layer, in which the adjacent layer contains an acid or a basic compound. There are also provided an optical filter using the light absorption filter and a manufacturing method for the optical filter, as well as an organic electroluminescent display device, an inorganic electroluminescent display device, and a liquid crystal display device, which include the optical filter.

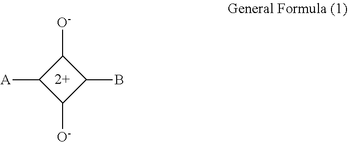

In the formula, A and B each independently represent an aryl group which may have a substituent, a heterocyclic group which may have a substituent, or —CH=G, where G represents a heterocyclic group which may have a substituent.

### CROSS-REFERENCE TO RELATED APPLICATIONS

This application is a Continuation of PCT International Application No. PCT/JP2023/007138 filed on Feb. 27, 2023, which was published under PCT Article 21(2) in Japanese, and which claims priority under 35 U.S.C. § 119 (a) to Japanese Patent Application No. 2022-029959 filed in Japan on Feb. 28, 2022. Each of the above applications is hereby expressly incorporated by reference, in its entirety, into the present application.

### BACKGROUND OF THE INVENTION

### 1. Field of the Invention

The present invention relates to a light absorption filter, an optical filter, a manufacturing method for the optical filter, an organic electroluminescent display device, an inorganic electroluminescent display device, and a liquid crystal display device.

### 2. Description of the Related Art

As image display devices, an organic electroluminescent (OLED) display device, an inorganic electroluminescent display device (inorganic EL display device), a liquid crystal display device, and the like have been used in recent years.

A liquid crystal display device is widely used year by year as a space-saving image display device with low power consumption. The liquid crystal display device is a non-light emitting element in which the liquid crystal panel itself displaying an image does not emit light, and thus the liquid crystal display device includes a backlight unit which is disposed on a rear surface of the liquid crystal panel and supplies light to the liquid crystal panel.

The OLED display device is a device that displays an image by utilizing self-luminescence of OLED elements. Therefore, the OLED display device has advantages that a high contrast ratio, a high color reproducibility, a wide viewing angle, a high-speed responsiveness, and a reduction in thickness and weight can be achieved, as compared with various display devices such as a liquid crystal display device and a plasma display device. In addition to these advantages, in terms of flexibility, research and development are being actively carried out as a next-generation display device.

The inorganic EL display device is a device that displays an image by utilizing self-luminescence of inorganic EL elements as a fluorescent material, instead of the OLED elements in the OLED display device. As a result of recent research, it is expected that a display device more excellent than the OLED display device in terms of a large screen size, a longer service life, and the like can be realized.

In the development of an image display device, it is known a technique of incorporating a light absorption filter as a configuration.

For example, WO2021/066082A discloses a laminate obtained by directly arranging a gas barrier layer on at least one surface of a wavelength selective absorption layer containing a dye having a main absorption wavelength band in a specific wavelength range and an antifading agent for a dye, where the gas barrier layer consists of a crystalline resin and has a thickness of 0.1 μm to 10 μm and an oxygen permeability of 60 cc/m²·day·atm or less. According to WO2021/066082A, in a case where this laminate is used as a means for antireflection of external light in an OLED display device instead of a circularly polarizing plate, it is said that excellent light resistance is exhibited and productivity is also excellent.

Regarding another form of the light absorption filter that is incorporated in an image display device, research has been also carried out on an optical filter having both a light absorptive portion having a light absorption effect and a portion in which the light absorbability has been eliminated (hereinafter, also simply referred to as a “light absorbability-eliminated portion”), which is obtained by eliminating the light absorbability of a desired portion. In particular, in a form in which an optical filter is used by being incorporated in an image display device, light absorption characteristics close to being colorless are required at a light absorbability-eliminated portion in the optical filter.

For example, WO2021/132674A discloses a light absorption filter containing a squarine-based coloring agent and a compound that generates a radical upon ultraviolet irradiation. According to the light absorption filter described in WO2021/132674A, it is said that a high decolorization rate is exhibited upon ultraviolet irradiation, and absorption derived from a new coloration structure (hereinafter, also referred to as “secondary absorption”) associated with the decomposition of the dye upon ultraviolet irradiation hardly occurs, whereby a high decolorization property can be obtained.

### SUMMARY OF THE INVENTION

As a result of the studies by the inventors of the present invention, it was found that in such a light absorption filter as described in WO2021/066082A or WO2021/132674A, there is room for improvement in at least one of the light resistance or the heat resistance of the coloring agent that is contained in the light absorption filter.

That is, an object of the present invention is to provide a light absorption filter having excellent light resistance and excellent heat resistance.

In addition, one embodiment of the present invention is to provide a light absorption filter that exhibits, in addition to the excellent light resistance and the excellent heat resistance, an excellent decolorization rate even in a case of being subjected to ultraviolet irradiation at room temperature and hardly causes secondary absorption associated with the decomposition of the coloring agent upon ultraviolet irradiation, and an optical filter using this light absorption filter, where the optical filter includes an optical filter having a light absorptive portion and a light absorbability-eliminated portion at a desired position, and an OLED display device, an inorganic electroluminescent display device, and a liquid crystal display device, which include this optical filter, as well as a manufacturing method for an optical filter.

As a result of diligent studies in consideration of the above problems, the inventors of the present invention found that excellent light resistance and excellent heat resistance can be obtained in a case where a light absorption filter is configured to be obtained by arranging an adjacent layer containing an acid or a basic compound, on a wavelength selective absorption layer containing a squarine-based coloring agent. In addition, in the configuration of the light absorption filter, it was found that in a case where the wavelength selective absorption layer further contains a compound A that has an acid group and a compound B that forms a hydrogen bond with the acid group contained in the compound A and generates a radical upon ultraviolet irradiation, in addition to the excellent light resistance and the excellent heat resistance, an excellent decolorization property can be obtained even in a case where ultraviolet rays are applied at room temperature (which means 10° C. to 30° C.), which is a mild environment. Further studies have been carried out based on these findings, whereby the present invention has been completed.

That is, the above object has been achieved by the following means.
<1> A light absorption filter comprising:
a wavelength selective absorption layer containing a resin and a squarine-based coloring agent represented by General Formula (1); and
an adjacent layer arranged on at least one surface of the wavelength selective absorption layer,
in which the adjacent layer contains an acid or a basic compound,

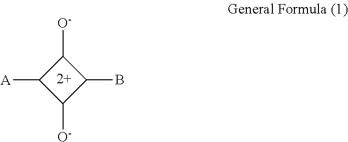

in the formula, A and B each independently represent an aryl group which may have a substituent, a heterocyclic group which may have a substituent, or —CH=G, where G represents a heterocyclic group which may have a substituent.
<2> The light absorption filter according to <1>, in which the wavelength selective absorption layer contains a compound A that has an acid group and a compound B that forms a hydrogen bond with the acid group contained in the compound A and generates a radical upon ultraviolet irradiation.
<3> The light absorption filter according to <2>, in which in the light absorption filter, the coloring agent is chemically changed to be decolorized upon ultraviolet irradiation.
<4> An optical filter that is obtained by subjecting the light absorption filter according to <2> or <3> to mask exposure by ultraviolet irradiation.
<5> An organic electroluminescent display device, an inorganic electroluminescent display device, or a liquid crystal display device, comprising:
the optical filter according to <4>.
<6> The organic electroluminescent display device, the inorganic electroluminescent display device, or the liquid crystal display device according to <5>,
in which a layer that inhibits light absorption of the compound B is provided on a viewer side with respect to the optical filter.
<7> A manufacturing method for an optical filter, comprising:
irradiating the light absorption filter according to <2> or <3> with an ultraviolet ray to carry out mask exposure.

In the present invention, in a case where there are a plurality of substituents, linking groups, and the like (hereinafter, referred to as substituents and the like) represented by specific reference numerals or formulae, or in a case where a plurality of substituents and the like are defined at the same time, the respective substituents and the like may be the same as or different from each other unless otherwise specified. The same applies to the definition of the number of substituents or the like. In addition, in a case where a plurality of substituents and the like come close to each other (particularly in a case where the substituents and the like are adjacent to each other), the substituents and the like may also be linked to each other to form a ring unless otherwise specified. In addition, unless otherwise specified, rings, for example, alicyclic rings, aromatic rings, and heterocyclic rings may be further fused to form a fused ring.

In the present invention, unless otherwise specified, the wavelength selective absorption layer may contain one kind or may contain two or more kinds of each of the components (the resin and the squarine-based coloring agent represented by General Formula (1)), which constitute the wavelength selective absorption layer in the light absorption filter, and the components that may be contained in the wavelength selective absorption layer (the compound A having an acid group, the compound B that forms a hydrogen bond with the acid group contained in the compound A and generating a radical upon ultraviolet irradiation, another component which may be appropriately contained, and the like). In addition, the adjacent layer may contain one kind or may contain two or more kinds of each of the components (the acid or the basic compound, another component which may be appropriately contained, and the like) constituting the adjacent layer in the light absorption filter according to the aspect of the present invention. The same also applies to the wavelength selective absorption layer and the adjacent layer in the optical filter that is produced by using the light absorption filter according to the aspect of the present invention.

In the optical filter according to the aspect of the present invention, the wavelength selective absorption layer in the light absorption filter according to the aspect of the present invention has alight absorbability-eliminated portion formed by ultraviolet irradiation. Unless otherwise specified, the description regarding the light absorption filter according to the aspect of the present invention can preferably apply to the optical filter according to the aspect of the present invention, except that it has this light absorbability-eliminated portion.

In the present invention, in a case where an E type double bond and a Z type double bond are present in a molecule, the double bond may be any one thereof or may be a mixture thereof, unless otherwise specified.

In the present invention, the representation of a compound (including a complex) is used to have a meaning including not only the compound itself but also a salt thereof, and an ion thereof. In addition, it is meant to include those in which a part of the structure is changed within a range where the effect of the present invention is not impaired. Furthermore, it is meant that a compound, which is not specified to be substituted or unsubstituted, may have any substituent within a range where the effect of the present invention is not impaired. The same applies to the definition of a substituent or a linking group.

In addition, in the present invention, the numerical value range indicated by using “to” means a range including the numerical values before and after “to” as the lower limit value and the upper limit value, respectively.

In the present invention, the “composition” includes a mixture in which the component concentration varies within a range in which a desired function is not impaired, in addition to a mixture in which the component concentration is constant (respective components are uniformly dispersed).

In the present invention, the description of “having a main absorption wavelength band in a wavelength range of XX to YY nm” means that a wavelength at which the maximal absorption is exhibited (that is, the maximal absorption wavelength) is present in the wavelength range of XX to YY nm. Therefore, in a case where the maximal absorption wavelength is present in the above-described wavelength range, the entire absorption band including this wavelength may be in the above-described wavelength range or may also extend up to the outside of the above-described wavelength range. In addition, in a case where there are a plurality of maximal absorption wavelengths, it suffices that a maximal absorption wavelength at which the highest absorbance is exhibited is present in the above-described wavelength range. That is, the maximal absorption wavelength other than the maximal absorption wavelength at which the highest absorbance is exhibited may be present either inside or outside the above-described wavelength range of XX to YY nm.

In the present invention, the main absorption wavelength band of a coloring agent is the main absorption wavelength band of the coloring agent, which is measured in the state of being a light absorption filter. Specifically, in the examples described later, it is measured in a state of being a base material-attached light absorption filter under the conditions described in the section of the absorbance of the light absorption filter.

The light absorption filter according to the aspect of the present invention exhibits excellent light resistance and excellent heat resistance.

In addition, in one embodiment of the light absorption filter according to the embodiment of the present invention, an excellent decolorization rate is exhibited in addition to the excellent light resistance and the excellent heat resistance in a case where ultraviolet irradiation is carried out at room temperature, and moreover, secondary absorption associated with the decomposition of the coloring agent upon ultraviolet irradiation hardly occurs.

In addition, the optical filter of the present invention, as well as the OLED display device, the inorganic electroluminescent display device, and the liquid crystal display device of the present invention, which include this optical filter, can have a light absorptive portion and a light absorbability-eliminated portion at a desired position.

In addition, according to the manufacturing method according to the aspect of the present invention, it is possible to obtain the optical filter according to the aspect of the present invention, which has a light absorptive portion and a light absorbability-eliminated portion at a desired position.

### BRIEF DESCRIPTION OF THE DRAWINGS

FIG. 1 is a schematic view illustrating an outline of one embodiment of a liquid crystal display device having an optical filter according to the present invention.

### DESCRIPTION OF THE PREFERRED EMBODIMENTS

### [Light Absorption Filter]

A light absorption filter according to an embodiment of the present invention contains a wavelength selective absorption layer containing a resin and a squarine-based coloring agent represented by General Formula (1) and contains an adjacent layer arranged on at least one surface of the wavelength selective absorption layer, where the adjacent layer contains an acid or a basic compound. The light absorption filter according to the embodiment of the present invention having such a configuration can exhibit excellent light resistance and excellent heat resistance. The reason for this is not clear; however, it is considered that controlling a change of pH in the wavelength selective absorption layer from the outside thereof contributes to the exhibition of the effect. Such an effect is supported by Examples described later.

In the wavelength selective absorption layer in the light absorption filter according to the embodiment of the present invention, a squarine-based coloring agent represented by General Formula (1) described later is dispersed (preferably dissolved) in the above-described resin, whereby a light absorption filter and a wavelength selective absorption layer are made to exhibit a specific absorption spectrum derived from the coloring agent. This dispersion may be any type of dispersion, such as a random type or a regular type.

In the light absorption filter according to the embodiment of the present invention, the “adjacent layer arranged on at least one surface of the wavelength selective absorption layer” may be arranged on the wavelength selective absorption layer while interposing another layer or may be directly arranged thereon without interposing another layer, as long as desired excellent light resistance and excellent heat resistance are obtained. Among the above, it is preferable to be directly arranged. That is, it is sufficient to have a form in which the acid or basic compound contained in the adjacent layer is capable of acting on the wavelength selective absorption layer.

In addition, since the squarine-based coloring agent represented by General Formula (1) which is contained in the light absorption filter according to the embodiment of the present invention hardly generates a secondary coloration structure associated with the decomposition of the coloring agent, it is possible to efficiently make a portion irradiated with ultraviolet light colorless. Therefore, in the light absorption filter according to the embodiment of the present invention, in a case of being configured to be capable of decolorizing the squarine-based coloring agent represented by General Formula (1) described later, the light absorption filter according to the embodiment of the present invention is to be such that the coloring agent has a characteristic of being capable of being chemically changed to decolorized upon irradiation with light (ultraviolet rays). As a result, by carrying out mask exposure by ultraviolet irradiation, it is possible to obtain the optical filter according to the embodiment of the present invention, which has both the light absorptive portion having a light absorption effect and the light absorbability-eliminated portion.

Examples of the configuration of the light absorption filter in which a coloring agent is capable of being decolorized with ultraviolet rays include a form in which the wavelength selective absorption layer in the light absorption filter according to the embodiment of the present invention contains a compound that generates a radical upon ultraviolet irradiation, as described in WO2021/132674A.

Among the above, examples thereof preferably include a light absorption filter which includes a wavelength selective absorption layer containing a resin, a squarine-based coloring agent represented by General Formula (1) described later, a compound A that has an acid group, and a compound B that forms a hydrogen bond with the acid group contained in this compound A and generates a radical upon ultraviolet irradiation, and which includes an adjacent layer arranged on at least one surface of the wavelength selective absorption layer, where the light absorption filter is such that the adjacent layer contains an acid or a basic compound (hereinafter, also referred to as “the light absorption filter I according to the embodiment of the present invention”).

In the wavelength selective absorption layer, “the compound A having an acid group” may be bonded to a polymer that constitutes a resin. Further, “the compound B that forms a hydrogen bond with the acid group contained in the compound A and generates a radical upon ultraviolet irradiation” described above is dispersed (preferably dissolved) in the resin by forming a hydrogen bond with the compound A or forms a hydrogen bond with the compound A in the resin in a case where the compound A containing the acid group is bonded to a polymer that constitutes the resin. The compound B generates a radical in a case of being subjected to ultraviolet irradiation, which makes it possible for a coloring agent to be faded with high efficiency and decolorized by a mechanism in which the generated radical reacts with the squarine-based coloring agent represented by General Formula (1).

The wavelength selective absorption layer in the light absorption filter I according to the embodiment of the present invention contains, in the resin, the squarine-based coloring agent represented by General Formula (1) described later, a compound A that has an acid group, and a compound B that forms a hydrogen bond with the acid group contained in the compound A and generates a radical upon ultraviolet irradiation. The light absorption filter I according to the embodiment of the present invention, which has the wavelength selective absorption layer having such a configuration can exhibit, as described above, an excellent decolorization property in addition to exhibiting excellent light resistance and excellent heat resistance even in a case of carrying out ultraviolet irradiation at room temperature (which means 10° C. to 30° C.), which is a mild environment. The presumable reason for this is considered to be as follows.

In a case where the wavelength selective absorption layer in the light absorption filter I according to the embodiment of the present invention contains the compound A having an acid group and the compound B that forms a hydrogen bond with the acid group of the compound A, it is considered that the efficiency of generating radical species upon ultraviolet irradiation is improved as compared with a case where a commonly used photoradical generator such as a benzophenone compound is used. As a result, even in a case where the ultraviolet irradiation is carried out under a mild temperature condition such as room temperature, sufficient radical species are generated, the radical species directly or indirectly react with the coloring agent, and then the coloring agent is decomposed, whereby the coloring agent is faded and decolorized. In particular, the squarine-based coloring agent represented by General Formula (1), which is contained in the wavelength selective absorption layer of the light absorption filter I according to the embodiment of the present invention can be decolorized without undergoing secondary absorption associated with the decomposition of the coloring agent.

In addition, in the light absorption filter I according to the embodiment of the present invention, in a case where the compound A having an acid group is bonded to a polymer that constitutes the resin, a radical is generated in the vicinity of the coloring agent upon ultraviolet irradiation, and an effect that the radical easily reacts with the coloring agent is exhibited.

In addition, the squarine-based coloring agent represented by General Formula (1) which is contained in the light absorption filter according to the embodiment of the present invention has a sharp absorption waveform in the main absorption wavelength band. Therefore, in a case of being used for an antireflection application, it is possible to more effectively prevent the reflection of external light while further suppressing the decrease in the transmittance of display light.

The wavelength selective absorption layer and the adjacent layer in the light absorption filter according to the embodiment of the present invention will be described in order.

### [Wavelength Selective Absorption Layer]

The wavelength selective absorption layer in the light absorption filter according to the embodiment of the present invention contains a resin and a squarine-based coloring agent represented by General Formula (1) (hereinafter, also simply referred to as a “coloring agent represented by General Formula (1)”).

### <Squarine-Based Coloring Agent Represented by General Formula (1)>

In the present invention, in the coloring agent represented by each General Formula, a cation is present in a delocalized manner, and thus a plurality of tautomer structures are present. Therefore, in the present invention, in a case where at least one tautomer structure of a certain coloring agent matches with each general formula, the certain coloring agent shall be a coloring agent represented by the general formula. Therefore, a coloring agent represented by a specific general formula can also be said to be a coloring agent having at least one tautomer structure that can be represented by the specific general formula. In the present invention, a coloring agent represented by a general formula may have any tautomer structure as long as at least one tautomer structure of the coloring agent matches with the general formula.

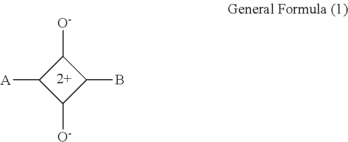

In General Formula (1), A and B each independently represent an aryl group which may have a substituent, a heterocyclic group which may have a substituent, or —CH=G. Here, G represents a heterocyclic group which may have a substituent.

The aryl group that can be employed as A or B is not particularly limited and may be a group consisting of a monocyclic ring or a group consisting of a fused ring. The aryl group preferably has 6 to 30 carbon atoms, more preferably 6 to 20 carbon atoms, and still more preferably 6 to 12 carbon atoms. Examples of the aryl group include groups respectively consisting of a benzene ring and a naphthalene ring, and a group consisting of a benzene ring is more preferable.

The heterocyclic group that can be employed as A or B is not particularly limited, and examples thereof include a group consisting of an aliphatic heterocyclic ring or an aromatic heterocyclic ring. A group consisting of an aromatic heterocyclic ring is preferable. Examples of the heteroaryl group that is an aromatic heterocyclic group include a heteroaryl group that can be employed as a substituent X described below. The aromatic heterocyclic group that can be employed as A or B is preferably a group of a 5-membered ring or a 6-membered ring and more preferably a group of a nitrogen-containing 5-membered ring. Specific examples thereof suitably include a group consisting of any of a pyrrole ring, a furan ring, a thiophene ring, an imidazole ring, a pyrazole ring, a thiazole ring, an oxazole ring, a triazole ring, an indole ring, an indolenine ring, an indoline ring, a pyridine ring, a pyrimidine ring, a quinoline ring, a benzothiazole ring, a benzoxazole ring, or a pyrazolotriazole ring. Among these, a group consisting of any of a pyrrole ring, a pyrazole ring, a thiazole ring, a pyridine ring, a pyrimidine ring, or a pyrazolotriazole ring is preferable. The pyrazolotriazole ring consists of a fused ring of a pyrazole ring and a triazole ring and may be a fused ring obtained by fusing at least one pyrazole ring and at least one triazole ring. Examples thereof include fused rings in General Formulae (4) and (5) described below.

A and B may be bonded to the squaric acid moiety (the 4-membered ring represented by General Formula (1)) at any portion (any ring-constituting atom) without particular limitation: however, they are preferably bonded at a carbon atom.

G in —CH=G that can be employed as A or B represents a heterocyclic group which may have a substituent, and examples thereof suitably include examples shown in the heterocyclic group that can be employed as A or B. Among these, a group consisting of any of a benzoxazole ring, a benzothiazole ring, an indoline ring, or the like is preferable.

At least one of A or B may have a hydrogen bonding group that forms an intramolecular hydrogen bond.

Each of A, B, and G may have the substituent X, and, in a case where A, B, or G has the substituent X, adjacent substituents may be bonded to each other to further form a ring structure. In addition, a plurality of substituents X may be present.

Examples of the substituent X include substituents that can be employed as R¹ in General Formula (2) described below. Specific examples thereof include a halogen atom, a cyano group, a nitro group, an alkyl group (including a cycloalkyl group), an alkenyl group, an alkynyl group, an aryl group, a heteroaryl group, an aralkyl group, and a ferrocenyl group, —OR¹⁰, —C(═O)R¹¹, —C(═O)OR¹², —OC(═O)R¹³, —NR¹⁴R¹⁵, —NHCOR¹⁶, —CONR¹⁷R¹⁸, —NHCONR¹⁹R²⁰, —NHCOOR²¹, —SR²², —SO₂R²³, —SO₃R²⁴, —NHSO₂R²⁵, and SO₂NR²⁶R²⁷. In addition, it is also preferable that the substituent X has a quencher moiety described later, in addition to the ferrocenyl group.

In General Formula (1), R¹⁰ to R²⁷ each independently represent a hydrogen atom, an aliphatic group, an aromatic group, or a heterocyclic group. The aliphatic group and the aromatic group that can be employed as R¹⁰ to R²⁷ are not particularly limited, and appropriately selected from an alkyl group, a cycloalkyl group, an alkenyl group, and an alkynyl group which are classified as aliphatic groups, and an aryl group which is classified as an aromatic group, in the substituent that can be employed as R¹ in General Formula (2) described later. The heterocyclic group that can be employed as R¹⁰ to R²⁷ may be aliphatic or aromatic, and it can be appropriately selected from heteroaryl groups or heterocyclic groups that can be employed as R¹ in General Formula (2) described below.

It is noted that in a case where R¹² of —COOR¹² is a hydrogen atom (that is, a carboxy group), the hydrogen atom may be dissociated (that is, a carbonate group) or may be in a salt state. In addition, in a case where R²⁴ of —SO₃R²⁴ is a hydrogen atom (that is, a sulfo group), the hydrogen atom may be dissociated (that is, a sulfonate group) or may be in a salt state.

Examples of the halogen atom that can be employed as the substituent X include a fluorine atom, a chlorine atom, a bromine atom, and an iodine atom.

The alkyl group that can be employed as the substituent X preferably has 1 to 20 carbon atoms, more preferably 1 to 15 carbon atoms, and still more preferably 1 to 8 carbon atoms. The alkenyl group preferably has 2 to 20 carbon atoms, more preferably 2 to 12 carbon atoms, and still more preferably 2 to 8 carbon atoms. The alkynyl group preferably has 2 to 40 carbon atoms, more preferably 2 to 30 carbon atoms, and particularly preferably 2 to 25 carbon atoms. The alkyl group, the alkenyl group, and the alkynyl group each may be linear, branched, or cyclic, and they are preferably linear or branched.

The aryl group that can be employed as the substituent X includes a monocyclic group or a fused ring group. The aryl group preferably has 6 to 30 carbon atoms, more preferably 6 to 20 carbon atoms, and still more preferably 6 to 12 carbon atoms.

An alkyl portion in the aralkyl group that can be employed as the substituent X is the same as that in the alkyl group. An aryl moiety in the aralkyl group is the same as the aryl group described above. The aralkyl group preferably has 7 to 40 carbon atoms, more preferably 7 to 30 carbon atoms, and still more preferably 7 to 25 carbon atoms.

The heteroaryl group that can be employed as the substituent X includes a group consisting of a single ring or a fused ring, a group consisting of a single ring or a fused ring having 2 to 8 rings is preferable, and a group consisting of a single ring or a fused ring having 2 to 4 rings is more preferable. The number of heteroatoms constituting the ring of the heteroaryl group is preferably 1 to 3. Examples of the heteroatom constituting the ring of the heteroaryl group include a nitrogen atom, an oxygen atom, and a sulfur atom. The heteroaryl group is preferably a group consisting of a 5-membered ring or a 6-membered ring. The number of carbon atoms constituting the ring in the heteroaryl group is preferably 3 to 30, more preferably 3 to 18, and still more preferably 3 to 12. Examples of the heteroaryl group include each group consisting of any of a pyridine ring, a piperidine ring, a furan ring, a furfuran ring, a thiophene ring, a pyrrole ring, a quinoline ring, a morpholine ring, an indole ring, an imidazole ring, a pyrazole ring, a carbazole ring, a phenothiazine ring, a phenoxazine ring, an indoline ring, a thiazole ring, a pyrazine ring, a thiadiazine ring, a benzoquinoline ring, or a thiadiazole ring.

The ferrocenyl group that can be employed as the substituent X is preferably represented by General Formula (2M).

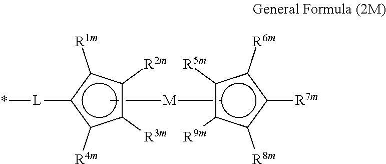

In General Formula (2M), L represents a single bond or a divalent linking group that does not conjugate with A, B, or G in General Formula (1). R^{1m} to R^{9m} each independently represent a hydrogen atom or a substituent. M represents an atom that can constitute a metallocene compound and represents Fe, Co, Ni, Ti, Cu, Zn, Zr, Cr, Mo, Os, Mn, Ru, Sn, Pd, Rh, V, or Pt. * represents a bonding site to A, B, or G.

In the present invention, in a case where L in General Formula (2M) is a single bond, a cyclopentadienyl ring directly bonded to A, B, or G (a ring having R^{1m} in General Formula (2M)) is not included in the conjugated structure which conjugates with A, B, or G.

The divalent linking group that can be employed as L is not particularly limited as long as it is a linking group that does not conjugate with A, B, or G, and it may have a conjugated structure in the inside thereof or at a cyclopentadiene ring side end part in General Formula (2M). Examples of the divalent linking group include an alkylene group having 1 to 20 carbon atoms, an arylene group having 6 to 20 carbon atoms, a divalent heterocyclic group obtained by removing two hydrogens from the heterocyclic ring, —CH═CH—, —CO—, —CS—, —NR—(R represents a hydrogen atom or a monovalent substituent), —O—, —S—, —SO₂—, or —N═CH—, or a divalent linking group formed by combining a plurality (preferably, 2 to 6) of these groups. The divalent linking group is preferably a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a divalent linking group in which two or more (preferably 2 to 6) selected from the above group are combined, and it is particularly preferably a group selected from the group consisting of an alkylene group having 1 to 4 carbon atoms, a phenylene group, —CO—, —NH—, —O—, and —SO₂—, or a linking group in which two or more (preferably 2 to 6) selected from the above group are combined. The divalent linking group combined is not particularly limited, and it is preferably a group containing —CO—, —NH—, —O—, or —SO₂—, and examples thereof include a linking group formed by combining two or more of —CO—, —NH—, —O—, or —SO₂—, or a linking group formed by combining at least one of —CO—, —NH—, —O—, or —SO₂— and an alkylene group or an arylene group. Examples of the linking group formed by combining two or more of —CO—, —NH—, —O—, or —SO₂— include —COO—, —OCO—, —CONH—, —NHCOO—, —NHCONH—, and —SO₂NH—. Examples of the linking group formed by combining at least one of —CO—, —NH—, —O—, or —SO₂— and an alkylene group or an arylene group include a group in which —CO—, —COO—, or —CONH— and an alkylene group or an arylene group are combined.

The substituent that can be employed as R is not particularly limited, and it has the same meaning as the substituent X which may be contained in A in General Formula (2).

L is preferably a single bond or a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined.

L may have one or a plurality of substituents. The substituent which may be contained in L is not particularly limited, and for example, it has the same meaning as the substituent X. In a case where L has a plurality of substituents, the substituents bonded to adjacent atoms may be bonded to each other to further form a ring structure.

The alkylene group that can be employed as L may be linear, branched, or cyclic as long as the group has 1 to 20 carbon atoms, and examples thereof include methylene, ethylene, propylene, methylethylene, methylmethylene, dimethylmethylene, 1,1-dimethylethylene, butylene, 1-methylpropylene, 2-methylpropylene, 1,2-dimethylpropylene, 1,3-dimethylpropylene, 1-methylbutylene, 2-methylbutylene, 3-methylbutylene, 4-methylbutylene, 2,4-dimethylbutylene, 1,3-dimethylbutylene, pentylene, hexylene, heptylene, octylene, ethane-1,1-diyl, propane-2,2-diyl, cyclopropane-1,1-diyl, cyclopropane-1,2-diyl, cyclobutane-1,1-diyl, cyclobutane-1,2-diyl, cyclopentane-1,1-diyl, cyclopentane-1,2-diyl, cyclopentane-1,3-diyl, cyclohexane-1,1-diyl, cyclohexane-1,2-diyl, cyclohexane-1,3-diyl, cyclohexane-1,4-diyl, and methylcyclohexane-1,4-diyl.

In a case where a linking group containing at least one of —CO—, —CS—, —NR— (R is as described above), —O—, —S—, —SO₂—, or —N═CH— in the alkylene group is employed as L, the group such as —CO— may be incorporated at any site in the alkylene group, and the number of the groups incorporated is not particularly limited.

The arylene group that can be employed as L is not particularly limited as long as the group has 6 to 20 carbon atoms, and examples thereof include a group obtained by further removing one hydrogen atom from each group exemplified as the aryl group having 6 to 20 carbon atoms that can be employed as A in General Formula (1).

The heterocyclic group that can be employed as L is not particularly limited, and examples thereof include a group obtained by further removing one hydrogen atom from each group exemplified as the heterocyclic group that can be employed as A.

In General Formula (2M), the remaining partial structure excluding the linking group L corresponds to a structure (a metallocene structure portion) in which one hydrogen atom is removed from the metallocene compound. In the present invention, for the metallocene compound serving as the metallocene structure portion, a publicly known metallocene compound can be used without particular limitation, as long as it is a compound conforming to the partial structure defined by General Formula (2M) (a compound in which a hydrogen atom is bonded instead of L). Hereinafter, the metallocene structure portion defined by General Formula (2M) will be specifically described.

In General Formula (2M), R^{1m} to R^{9m} each independently represent a hydrogen atom or a substituent. The substituents that can be employed as R^{1m} to R^{9m} are not particularly limited, and can be selected from, for example, the substituents that can be employed as R¹ in General Formula (3). R^{1m} to R^{9m} each are preferably a hydrogen atom, a halogen atom, an alkyl group, an acyl group, an alkoxy group, an amino group, or an amide group, more preferably a hydrogen atom, a halogen atom, an alkyl group, an acyl group, or an alkoxy group, still more preferably a hydrogen atom, a halogen atom, an alkyl group, or an acyl group, particularly preferably a hydrogen atom, a halogen atom, or an alkyl group, and most preferably a hydrogen atom.

As the alkyl group that can be employed as R^{1m} to R^{9m}, among the alkyl groups that can be employed as R¹, an alkyl group having 1 to 8 carbon atoms is preferable, and examples thereof include methyl, ethyl, propyl, isopropyl, butyl, sec-butyl, tert-butyl, isobutyl, pentyl, tert-pentyl, hexyl, octyl, and 2-ethylhexyl.

This alkyl group may have a halogen atom as a substituent. Examples of the alkyl group substituted with a halogen atom include chloromethyl, dichloromethyl, trichloromethyl, bromomethyl, dibromomethyl, tribromomethyl, fluoromethyl, difluoromethyl, trifluoromethyl, 2,2,2-trifluoroethyl, perfluoroethyl, perfluoropropyl, and perfluorobutyl.

In addition, in the alkyl group that can be employed as R^{1m} or the like, at least one methylene group that forms a carbon chain may be substituted with —O— or —CO—. Examples of the alkyl group in which the methylene group is substituted with —O— include, for example, an alkyl group in which the end part methylene group of methoxy, ethoxy, propoxy, isopropoxy, isobutoxy, sec-butoxy, tert-butoxy, 2-methoxyethoxy, chloromethyloxy, dichloromethyloxy, trichloromethyloxy, bromomethyloxy, dibromomethyloxy, tribromomethyloxy, fluoromethyloxy, difluoromethyloxy, trifluoromethyloxy, 2,2,2-trifluoroethyloxy, perfluoroethyloxy, perfluoropropyloxy, or perfluorobutyloxy is substituted, and an alkyl group in which an internal methylene group of the carbon chain such as 2-methoxyethyl or the like is substituted. Examples of the alkyl group in which a methylene group is substituted with —CO— include acetyl, propionyl, monochloroacetyl, dichloroacetyl, trichloroacetyl, trifluoroacetyl, propane-2-one-1-yl, and butane-2-one-1-yl.

In General Formula (2M), M represents an atom that can constitute a metallocene compound, and represents Fe, Co, Ni, Ti, Cu, Zn, Zr, Cr, Mo, Os, Mn, Ru, Sn, Pd, Rh, V, or Pt. Among these, M is preferably Fe, Ti, Co, Ni, Zr, Ru, or Os, more preferably Fe, Ti, Ni, Ru, or Os, still more preferably Fe or Ti, and most preferably Fe.

The group represented by General Formula (2M) is preferably a group formed by combining preferred ones of L, R^{1m} to R^{9m}, and M. Examples thereof include a group formed by combining, as L, a single bond, or a group selected from the group consisting of an alkylene group having 2 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined; as R^{1m} to R^{9m}, a hydrogen atom, a halogen atom, an alkyl group, an acyl group, or an alkoxy group; and as M, Fe.

The alkyl group, the alkenyl group, the alkynyl group, the aralkyl group, the aryl group, and the heteroaryl group which can be employed as the substituent X and the aliphatic group, the aromatic group, and the heterocyclic group which can be employed as R¹⁰ to R²⁷ each may further have a substituent or may be unsubstituted. The substituent which may be further contained therein is not particularly limited, and it is preferably a substituent selected from an alkyl group, an aryl group, an amino group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, a sulfonylamino group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group, and it is more preferably a substituent selected from an alkyl group, an aryl group, an alkoxy group, an aryloxy group, an aromatic heterocyclic oxy group, an acyl group, an alkoxycarbonyl group, an aryloxycarbonyl group, an acyloxy group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group. This group can be appropriately selected from the substituents that can be employed as R¹ in General Formula (2) described below.

One preferred embodiment of the coloring agent represented by General Formula (1) includes a coloring agent represented by General Formula (2).

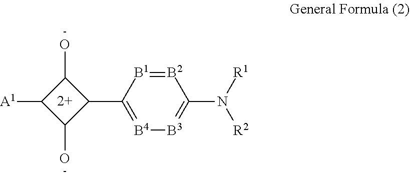

In General Formula (2), A¹ is the same as A in General Formula (1). Among these, a heterocyclic group which is a nitrogen-containing 5-membered ring is preferable.

In General Formula (2), R¹ and R² each independently represent a hydrogen atom or a substituent. R¹ and R² may be the same or different from each other, and they may be bonded together to form a ring.

The substituents that can be employed as R¹ and R² are not particularly limited, and examples thereof include an alkyl group (a methyl group, an ethyl group, a propyl group, an isopropyl group, a butyl group, a t-butyl group, an isobutyl group, a pentyl group, a hexyl group, an octyl group, a dodecyl group, a trifluoromethyl group, or the like), a cycloalkyl group (a cyclopentyl group, a cyclohexyl group, or the like), an alkenyl group (a vinyl group, an allyl group, or the like), an alkynyl group (an ethynyl group, a propargyl group, or the like), an aryl group (a phenyl group, a naphthyl group, or the like), a heteroaryl group (a furyl group, a thienyl group, a pyridyl group, a pyridazyl group, a pyrimidyl group, a pyrazyl group, a triazyl group, an imidazolyl group, a pyrazolyl group, a thiazolyl group, a benzimidazolyl group, a benzoxazolyl group, a quinazolyl group, a phthalazyl group, or the like), a heterocyclic group (also referred to as a heterocyclic group, for example, a pyrrolidyl group, an imidazolidyl group, a morpholyl group, an oxazolidyl group, or the like), an alkoxy group (a methoxy group, an ethoxy group, a propyloxy group, or the like), a cycloalkoxy group (a cyclopentyloxy group, a cyclohexyloxy group, or the like), an aryloxy group (a phenoxy group, a naphthyloxy group, or the like), a heteroaryloxy group (an aromatic heterocyclic oxy group), an alkylthio a group (a methylthio group, an ethylthio group, a propylthio group, or the like), a cycloalkylthio group (a cyclopentylthio group, a cyclohexylthio group, or the like), an arylthio group (a phenylthio group, a naphthylthio group, or the like), a heteroarylthio group (an aromatic heterocyclic thio group), an alkoxycarbonyl group (a methyloxycarbonyl group, an ethyloxycarbonyl group, a butyloxycarbonyl group, an octyloxycarbonyl group, or the like), an aryloxycarbonyl group (a phenyloxycarbonyl group, a naphthyloxycarbonyl group, or the like), a phosphoryl group (dimethoxyphosphonyl or diphenylphosphoryl), a sulfamoyl a group (an aminosulfonyl group, a methylaminosulfonyl group, a dimethylaminosulfonyl group, a butylaminosulfonyl group, a cyclohexylaminosulfonyl group, an octylaminosulfonyl group, a phenylaminosulfonyl group, a 2-pyridylaminosulfonyl group, or the like), an ancyl a group (an acetyl group, an ethylcarbonyl group, a propylcarbonyl group, a cyclohexylcarbonyl group, an octylcarbonyl group, a 2-ethylhexylcarbonyl group, a phenylcarbonyl group, a naphthylcarbonyl group, a pyridylcarbonyl group, or the like), an acyloxy group (an acetyloxy group, an ethylcarbonyloxy group, a butylcarbonyloxy group, an octylcarbonyloxy group, a phenylcarbonyloxy group, or the like), an amide group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, or the like), a sulfonylamide group (a methylsulfonylamino group, an octylsulfonylamino group, a 2-ethylhexylsulfonylamino group, a trifluoromethylsulfonylamino group, or the like), a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, or the like), a ureide group (a methylureide group, an ethylureide group, a pentylureide group, a cyclohexylureide group, an octylureide group, a dodecylureide group, a phenylureide group, a naphthylureide group, a 2-pyridylaminoureide group, or the like), an alkylsulfonyl group (a methylsulfonyl group, an ethylsulfonyl group, a butylsulfonyl group, a cyclohexylsulfonyl group, a 2-ethylhexylsulfonyl group, or the like), an arylsulfonyl group (a phenylsulfonyl group, a naphthylsulfonyl group, a 2-pyridylsulfonyl group, or the like), an amino group (an amino group, an ethylamino group, a dimethylamino group, a butylamino group, a dibutylamino group, a cyclopentylamino group, a 2-ethylhexylamino group, a dodecylamino group, an anilino group, a naphthylamino group, a 2-pyridylamino group, or the like), an alkylsulfonyloxy group (methanesulfonyloxy), a cyano group, a nitro group, halogen atoms (a fluorine atom, a chlorine atom, a bromine atom, or the like), and a hydroxy group.

Among these, an alkyl group, an alkenyl group, an aryl group, or a heteroaryl group is preferable, an alkyl group, an aryl group, or a heteroaryl group is more preferable, and an alkyl group is still more preferable.

The substituent that can be employed as R¹ and R² may further have a substituent. Examples of the substituent which may be further contained therein include the substituent that can be employed as R¹ and R², and the substituent X which may be contained in A, B, and G in General Formula (1) described above. In addition, R¹ and R² may be bonded to each other to form a ring, and R¹ or R² and the substituent contained in B² or B³ may be bonded to each other to form a ring.

The ring that is formed in this case is preferably a heterocyclic ring or a heteroaryl ring, and it is preferably a 5-membered ring or a 6-membered ring although the size of the ring to be formed is not particularly limited. In addition, the number of rings to be formed is not particularly limited, and it may be one or may be two or more. Examples of the form in which two or more rings are formed include a form in which the substituents of R¹ and B² and the substituents contained in R² and B³ are respectively bonded to each other to form two rings.

In General Formula (2), B¹, B², B³, and B⁴ each independently represent a carbon atom or a nitrogen atom. The ring including B¹, B², B³, and B⁴ is an aromatic ring. It is preferable that at least two or more of B¹ to B⁴ are a carbon atom, and it is more preferable that all of B¹ to B⁴ are a carbon atom.

The carbon atom that can be employed as B¹ to B⁴ has a hydrogen atom or a substituent. Among carbon atoms that can be employed as B¹ to B⁴, the number of carbon atoms having a substituent is not particularly limited; however, it is preferably zero, one, or two, and more preferably one. Particularly, it is preferable that B¹ and B⁴ are a carbon atom and at least one of them has a substituent.

The substituent possessed by the carbon atom that can be employed as B¹ to B⁴ is not particularly limited, and examples thereof include the above-described substituents that can be employed as R¹ and R². Among these, it is preferably an alkyl group, an alkoxy group, an alkoxycarbonyl group, an aryl group, an acyl group, an amide group, a sulfonylamide group, a carbamoyl group, an alkylsulfonyl group, an arylsulfonyl group, an amino group, a cyano group, a nitro group, a halogen atom, or a hydroxy group, and it is more preferably an alkyl group, an alkoxy group, an alkoxycarbonyl group, an aryl group, an acyl group, an amide group, a sulfonylamide group, a carbamoyl group, an amino group, a cyano group, a nitro group, a halogen atom, or a hydroxy group.

The substituent possessed by the carbon atom that can be adopted as B¹ to B⁴ may further have a substituent. The substituents that may be further possessed by the carbon atom include the substituent which may be further contained in R¹ and R² in General Formula (2) described above and the substituent X which may be contained in A, B, and G in General Formula (1) described above, where a ferrocenyl group is preferable.

Examples of the substituent that can be possessed by the carbon atom that can be employed as B¹ and B⁴ still more preferably include an alkyl group, an alkoxy group, a hydroxy group, an amide group, a sulfonylamide group, or a carbamoyl group, and particularly preferably an alkyl group, an alkoxy group, a hydroxy group, an amide group, or a sulfonylamide group, and a hydroxy group, an amide group, or a sulfonylamide group is most preferable. The substituent possessed by the carbon atom that can be employed as B¹ and B⁴ may further have a ferrocenyl group.

It is still more preferable that the substituent that can be possessed by the carbon atom that can be employed as B² and B³ is an alkyl group, an alkoxy group, an alkoxycarbonyl group, an acyl group, an amino group, a cyano group, a nitro group, or a halogen atom, and it is particularly preferable that the substituent as any one of B² or B³ is an electron withdrawing group (for example, an alkoxycarbonyl group, an acyl group, a cyano group, a nitro group, or a halogen atom).

The coloring agent represented by General Formula (2) is preferably a coloring agent represented by any of General Formulae (3), (4), or (5).

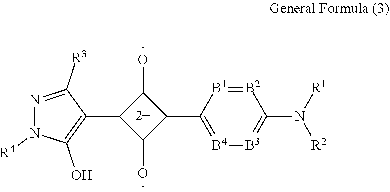

In General Formula (3), R¹ and R² each independently represent a hydrogen atom or a substituent, and they respectively have the same meanings as R¹ and R² in General Formula (2), where the same applies to the preferred ranges thereof.

In General Formula (3), B¹ to B⁴ each independently represent a carbon atom or a nitrogen atom, and they have respectively the same meanings as B¹ to B⁴ in General Formula (2), where the same applies to the preferred ranges thereof.

In General Formula (3), R³ and R⁴ each independently represent a hydrogen atom or a substituent. The substituent that can be employed as R³ and R⁴ is not particularly limited, and examples thereof include the same ones as the substituents that can be employed as R¹ and R².

However, the substituent that can be employed as R³ is preferably an alkyl group, an alkoxy group, an amino group, an amide group, a sulfonylamide group, a cyano group, a nitro group, an aryl group, a heteroaryl group, a heterocyclic group, an alkoxycarbonyl group, a carbamoyl group, or a halogen atom, more preferably an alkyl group, an aryl group, or an amino group, and still more preferably an alkyl group. This substituent that can be employed as R³ may further have a ferrocenyl group.

The substituent that can be employed as R⁴ is preferably an alkyl group, an aryl group, a heteroaryl group, a heterocyclic group, an alkoxy group, an alkoxycarbonyl group, an acyl group, an acyloxy group, an amide group, a carbamoyl group, an amino group, or a cyano group, more preferably an alkyl group, an alkoxycarbonyl group, an acyl group, a carbamoyl group, or an aryl group, and still more preferably an alkyl group.

The alkyl group that can be employed as R³ and R⁴ may be either linear, branched, or cyclic, and it is preferably linear or branched. The alkyl group preferably has 1 to 12 carbon atoms and more preferably 1 to 8 carbon atoms. An example of the alkyl group is preferably a methyl group, an ethyl group, an n-propyl group, an isopropyl group, a t-butyl group, a 2-ethylhexyl group, or a cyclohexyl group, and more preferably a methyl group or a t-butyl group.

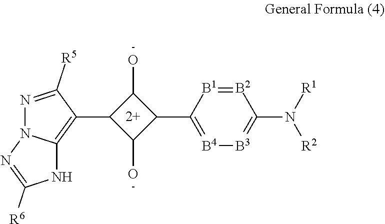

In General Formula (4), R¹ and R² each independently represent a hydrogen atom or a substituent, and they respectively have the same meanings as R¹ and R² in General Formula (2), where the same applies to the preferred ranges thereof.

In General Formula (4), B¹ to B⁴ each independently represent a carbon atom or a nitrogen atom, and they have respectively the same meanings as B¹ to B⁴ in General Formula (2), where the same applies to the preferred ranges thereof.

In General Formula (4), R⁵ and R⁶ each independently represent a hydrogen atom or a substituent. The substituent that can be employed as R⁵ and R⁶ is not particularly limited, and examples thereof include the same ones as the substituents that can be employed as R¹ and R².

However, the substituent that can be employed as R⁵ is preferably an alkyl group, an alkoxy group, an aryloxy group, an amino group, a cyano group, an aryl group, a heteroaryl group, a heterocyclic group, an acyl group, an acyloxy group, an amide group, a sulfonylamide group, an ureide group, or a carbamoyl group, more preferably an alkyl group, an alkoxy group, an acyl group, an amide group, or an amino group, and still more preferably an alkyl group.

The alkyl group that can be employed as R⁵ has the same meaning as the alkyl group that can be employed as R³ in General Formula (3), and the same applies to the preferred range thereof.

In General Formula (4), the substituent that can be employed as R⁶ is preferably an alkyl group, an alkenyl group, an aryl group, a heteroaryl group, a heterocyclic group, an alkoxy group, a cycloalkoxy group, an aryloxy group, an alkoxycarbonyl group, an acyl group, an acyloxy group, an amide group, a sulfonylamide group, an alkylsulfonyl group, an arylsulfonyl group, a carbamoyl group, an amino group, a cyano group, a nitro group, or a halogen atom, more preferably an alkyl group, an aryl group, a heteroaryl group, or a heterocyclic group, and still more preferably an alkyl group or an aryl group.

The alkyl group that can be employed as R⁶ has the same meaning as the alkyl group that can be employed as R⁴ in General Formula (3), and the same applies to the preferred range thereof.

The aryl group that can be employed as R⁶ is preferably an aryl group having 6 to 12 carbon atoms, and more preferably a phenyl group. This aryl group may have a substituent, and examples of such a substituent include a group included in the following substituent group A, and an alkyl group, a sulfonyl group, an amino group, an acylamino group, a sulfonylamino group, or the like, which have 1 to 10 carbon atoms, is particularly preferable. This substituent may further have a substituent. Specifically, the substituent is preferably an alkylsulfonylamino group.

### —Substituent Group A—

A halogen atom, an alkyl group, an alkenyl group, an alkynyl group, an aryl group, a heterocyclic group, a cyano group, a hydroxy group, a nitro group, a carboxy group, an alkoxy group, an aminooxy group, an aryloxy group, a silyloxy group, a heterocyclic oxy group, an acyloxy group, a carbamoyloxy group, an amino group, an acylamino group, an aminocarbonylamino group, an alkoxycarbonylamino group, an aryloxycarbonylamino group, a sulfamoylamino group, a sulfonylamino group (including an alkyl or arylsulfonylamino group), a mercapto group, an alkylthio group, an arylthio group, a heterocyclic thio group, a sulfamoyl group, a sulfo group, an alkyl or arylsulfonyl group, a sulfonyl group (including an alkyl or arylsulfinyl group), an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a silyl group.

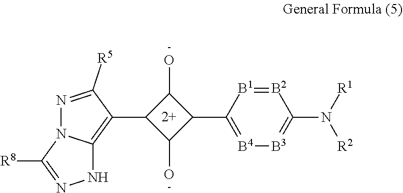

In General Formula (5), R¹ and R² each independently represent a hydrogen atom or a substituent, and they respectively have the same meanings as R¹ and R² in General Formula (2), where the same applies to the preferred ranges thereof.

In General Formula (5), B¹ to B⁴ each independently represent a carbon atom or a nitrogen atom, and they have respectively the same meanings as B¹ to B⁴ in General Formula (2), where the same applies to the preferred ranges thereof.

In General Formula (5), R⁷ and R⁸ each independently represent a hydrogen atom or a substituent. The substituent that can be employed as R⁷ and R¹ is not particularly limited, and examples thereof include the same ones as the substituents that can be employed as R¹ and R².

However, the preferred range, the more preferred range, and the still more preferred range of the substituent that can be employed as R⁷ are the same as those of the substituent that can be employed as R⁵ in General Formula (4). The alkyl group that can be employed as R⁵ has the same meaning as the alkyl group that can be employed as R³, and the same applies to the preferred range thereof.

In General Formula (5), the preferred range, the more preferred range, and the still more preferred range of the substituent that can be employed as R⁸ are the same as those of the substituent that can be employed as R⁶ in General Formula (4). The preferred ranges of the alkyl group and the aryl group that can be employed as R⁸ have the same meaning as the alkyl group and the aryl group that can be employed as R⁶ in General Formula (4), where the same applies to the preferred ranges thereof.

Examples of the squarine-based coloring agent represented by any of General Formulae (1) to (5) include compounds described in any of JP2006-160618A, WO2004/005981A, WO2004/007447A, Dyes and Pigment, 2001, 49, p. 161 to 179, WO2008/090757A, WO2005/121098A, and JP2008-275726A.

Specific examples of the coloring agent represented by any one of General Formula (1) to General Formula (5) include the compounds described in [0067] to [0070] of WO2022/149510A. However, the present invention is not limited thereto.

In addition, in addition to the above-described specific examples, specific examples of the coloring agent represented by any one of General Formulae (3) to (5) include the compounds described in [0071] to [0080] of WO2022/149510A. However, the present invention is not limited thereto.

In addition, for the one preferred embodiment of the coloring agent represented by General Formula (1), the description regarding the coloring agent represented by any of General Formulae (6) to (9) described in [0081] to [0095] of WO2021/132674A and the specific examples thereof can be applied as they are.

### (Quencher-Embedded Coloring Agent)

The squarine-based coloring agent represented by General Formula (1) may be a quencher-embedded coloring agent in which a quencher moiety is linked to a coloring agent by a covalent bond through a linking group. The quencher-embedded coloring agent can also be preferably used as the above coloring agent.

Examples of the quencher-embedded coloring agent include an electron-donating quencher-embedded coloring agent in which the quencher moiety is an electron-donating quencher moiety, and an electron-accepting quencher moiety in which the quencher moiety is an electron-accepting quencher moiety.

The electron-donating quencher moiety means a structure portion that inactivates a coloring agent in the excited state to the ground state by donating an electron to a SOMO (singly occupied molecular orbital) at a low energy level of two SOMO's of the coloring agent in the excited state and then receiving an electron from a SOMO at a high energy level of the coloring agent. The electron-accepting quencher moiety means a structure portion that inactivates a coloring agent in the excited state to the ground state by accepting an electron from a SOMO at a high energy level of two SOMO's of the coloring agent in the excited state and then donating an electron to a SOMO at a low energy level of the coloring agent.

Examples of the electron-donating quencher moiety include the ferrocenyl group in the substituent X described above, and the quencher moieties in the quencher compounds described in paragraphs [0199] to [0212] and paragraphs [0234] to [0287] of WO2019/066043A, where the ferrocenyl group in the substituent X described above is preferable. In addition, examples of the electron-accepting quencher moiety include the quencher moieties in the quencher compounds described in paragraphs [0288] to [0310] of WO2019/066043A.

From the viewpoint of light resistance, the wavelength selective absorption layer in the light absorption filter according to the embodiment of the present invention is such that the squarine-based coloring agent represented by General Formula (1) preferably includes an electron-donating quencher-embedded coloring agent and more preferably includes a squarine-based coloring agent represented by General Formula (1A).

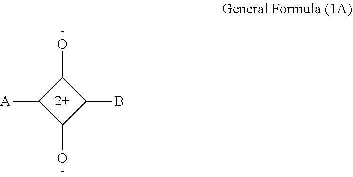

In the formula, A and B each independently have an aryl group or a substituent which may have a substituent.

Indicates a heterocyclic group which may have or —CH=G. Here, G represents a heterocyclic group which may have a substituent. However, at least one of A or B includes an electron-donating quencher moiety.

The coloring agent represented by General Formula (1A) is the same as the coloring agent represented by (1) described later, except that in the coloring agent represented by General Formula (1) described above, at least one of A or B includes an electron-donating quencher moiety. As a result, the description related to A, B, and G in General Formula (1) can be applied to the description related to A, B, and G in General Formula (1A). In addition, as a preferred embodiment of the coloring agent represented by General Formula (1A), a description in which, in the description of the coloring agent represented by any of General Formulae (2) to (9), which is a preferred embodiment of the coloring agent represented General Formula (1), at least one of the structures corresponding to A and B in General Formula (1) is changed to include an electron-donating quencher moiety can be applied.

The electron-donating quencher moiety contained in at least one of A and B is preferably the ferrocenyl group in the substituent X described above.

Specific examples of the coloring agent represented by any of General Formula (1) to General Formula (5) include the compounds described in [0098] to [0114] of WO2021/132674A. However, the present invention is not limited thereto.

In the light absorption filter according to the embodiment of the present invention, the content of the squarine-based coloring agent represented by General Formula (1) is preferably 0.01 to 30 parts by mass and more preferably 0.1 to 10 parts by mass in 100 parts by mass of the wavelength selective absorption layer in the light absorption filter according to the embodiment of the present invention.

It is noted that in a case where the wavelength selective absorption layer in the light absorption filter according to the embodiment of the present invention contains the above-described quencher-embedded coloring agent, the content of the quencher-embedded coloring agent is, from the viewpoint of imparting the favorable light absorbability such as the antireflection effect, preferably 0.10 parts by mass or more, more preferably 0.15 parts by mass or more, still more preferably 0.20 parts by mass or more, particularly preferably 0.25 parts by mass or more, and especially preferably 0.30 parts by mass or more, with respect to 100 parts by mass of the resin constituting the wavelength selective absorption layer in the light absorption filter according to the embodiment of the present invention. The upper limit value thereof is preferably 45 parts by mass or less, preferably 40 parts by mass or less, more preferably 30 parts by mass or less, still more preferably 15 parts by mass or less, particularly preferably 10 parts by mass or less, and especially preferably 5 parts by mass or less. In 100 parts by mass of the wavelength selective absorption layer in the light absorption filter according to the embodiment of the present invention, the content of the quencher-embedded coloring agent is preferably 0.10 to 45 parts by mass, more preferably 0.15 to 40 parts by mass, still more preferably 0.20 to 30 parts by mass, particularly preferably 0.25 to 15 parts by mass, and especially preferably 0.30 to 10 parts by mass.

The squarine-based coloring agent represented by General Formula (1), which is contained in the wavelength selective absorption layer, may be one kind or may be two or more kinds. In a case where the wavelength selective absorption layer contains two or more kinds of squarine-based coloring agents represented by General Formula (1), the description related to the above-described content means the total content of two or more kinds of squarine-based coloring agents represented by General Formula (1).

The squarine-based coloring agent represented by General Formula (1) preferably has a main absorption wavelength band in a wavelength range of 400 to 700 nm.

In addition, the wavelength selective absorption layer can contain a coloring agent other than the squarine-based coloring agent represented by General Formula (1) (including a dye; hereinafter, referred to as “another coloring agent”). Examples of the other coloring agents include coloring agents having a main absorption wavelength band in a wavelength range of 400 to 700 nm, and specific examples thereof include coloring agents (dyes) which are a tetraazaporphyrin (TAP) type, a cyanine (CY) type, a benzylidene type, and a cinnamylidene type, respectively.

In the light absorption filter according to the embodiment of the present invention, the total content of the coloring agent is preferably 0.10 parts by mass or more, more preferably 0.15 parts by mass or more, still more preferably 0.20 parts by mass or more, particularly preferably 0.25 parts by mass or more, and especially preferably 0.30 parts by mass or more, in 100 parts by mass of the wavelength selective absorption layer in the light absorption filter according to the embodiment of the present invention. In a case where the total content of the coloring agent in the wavelength selective absorption layer in the light absorption filter according to the embodiment of the present invention is equal to or larger than the above-described preferred lower limit value, a favorable antireflection effect can be obtained.

In addition, in the light absorption filter according to the embodiment of the present invention, the total content of the coloring agents is generally 50 parts by mass or less, preferably 40 parts by mass or less, more preferably 30 parts by mass or less, still more preferably 15 parts by mass or less, and particularly preferably 10 parts by mass or less, with respect to 100 parts by mass of the wavelength selective absorption layer in the light absorption filter according to the embodiment of the present invention.

### <Resin>

In the light absorption filter according to the embodiment of the present invention, the resin contained in the wavelength selective absorption layer described above (hereinafter, also referred to as a “matrix resin”) is not particularly limited as long as it can disperse (preferably dissolve) the coloring agent described above and has the desired light transmittance (the light transmittance is preferably 80% or more in the visible range in a wavelength of 400 to 800 nm).

In addition to the above, it is not particularly limited as long as the decolorization action of the coloring agent due to the radical generated from the compound B that is hydrogen-bonded to the acid group in the compound A can be exhibited in the light absorption filter I according to the embodiment of the present invention.

As a polymer that constitutes the above-described resin, various polymers can be used. From the viewpoint that the molecular weight of the resin is not easily reduced upon ultraviolet irradiation, a polymer having an aromatic ring or an alicyclic structure in the side chain is preferable, and a (meth)acrylic polymer containing a constitutional unit having an aromatic ring or an alicyclic structure is more preferable. Among the above, from the viewpoint of further improving the decolorization rate and further improving the heat resistance and the light resistance as well, a (meth)acrylic polymer containing a constitutional unit having an alicyclic structure in the side chain is still more preferable.

Here, the (meth)acrylic polymer refers to a polymer containing at least one of a constitutional unit derived from (meth)acrylic acid or a constitutional unit derived from (meth)acrylic acid ester. It is noted that the constitutional unit derived from (meth)acrylic acid is a constitutional unit described later which has a carboxy group as an acid group in the compound A, in a case where the polymer contains a constitutional unit derived from (meth)acrylic acid, and the polymer corresponds to a polymer described later in which the compound A described later is chemically bonded to the above-described polymer that constitutes the resin.

In addition, in the present disclosure, the “main chain” represents a relatively longest bonding chain in a molecule of a high-molecular-weight compound, and the “side chain” represents an atomic group branched from the main chain.

Examples of the monomer from which a constitutional unit having an aromatic ring is derived include benzyl acrylate, benzyl methacrylate, naphthyl acrylate, naphthyl methacrylate, naphthyl methyl acrylate, and naphthyl methyl methacrylate. The content of the constitutional unit having an aromatic ring is preferably 5% to 100% by mass, more preferably 10% to 100% by mass, and still more preferably 20% to 100% by mass, with respect to the total mass of the polymer.

Examples of the monomer from which a constitutional unit having an alicyclic structure is derived include dicyclopentanyl (meth)acrylate, cyclohexyl (meth)acrylate, and isobornyl (meth)acrylate.

In a case where the polymer contains a constitutional unit having an alicyclic structure, the content of the constitutional unit having an alicyclic structure is preferably 1% to 90% by mass, more preferably 5% to 90% by mass, and still more preferably 5% to 80% by mass, with respect to the total mass of the polymer.

In addition, in the light absorption filter in the wavelength selective absorption layer according to the embodiment of the present invention, the polymer that constitutes the resin may contain a constitutional unit bonded to the compound A having an acid group. The constitutional unit bonded to the compound A having an acid group is preferably a constitutional unit derived from (meth)acrylic acid. The content of the constitutional unit derived from (meth)acrylic acid is preferably 1% to 70% by mass and more preferably 1% to 60% by mass with respect to the total mass of the polymer. More preferably, the description of the content of the constitutional unit described later which has the carboxy group of the carboxy group-containing polymer in the compound A is applied thereto.

In addition, in a case where the polymer that constitutes the resin contains a constitutional unit bonded to the compound A having an acid group, the descriptions of the content of the constitutional unit having the aromatic ring of the carboxy group-containing polymer regarding the compound A and the constitutional unit having an alicyclic structure, which will be described later, are applied to the content of the constitutional unit having an aromatic ring and the content of the constitutional unit having an alicyclic structure.

From the viewpoint of adjusting the glass transition temperature and the like, the polymer that constitutes the resin may contain a constitutional unit that has an alkyl group having 1 to 14 carbon atoms. Examples of the constitutional unit having an alkyl group having 1 to 14 carbon atoms include a constitutional unit derived from an alkyl (meth)acrylate, such as methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl (meth)acrylate, 2-ethylhexyl (meth)acrylate, 2-ethylbutyl (meth)acrylate, n-octyl (meth)acrylate, isooctyl (meth)acrylate, isononyl (meth)acrylate, lauryl (meth)acrylate, or tetradecyl (meth)acrylate. In the present invention, one kind of the constitutional unit having an alkyl group having 1 to 14 carbon atoms may be used alone, or two or more kinds thereof may be used in combination. The content of the constitutional unit having an alkyl group having 1 to 14 carbon atoms is preferably 0% by mass to 95% by mass with respect to the total mass of the polymer that constitutes the resin.

The weight-average molecular weight (Mw) of the polymer that constitutes the resin is preferably 10,000 or more, more preferably 10,000 to 200,000, and still more preferably 15,000 to 150,000.

In addition, as another example of the above-described the embodiment of the resin, the description of the matrix resin described in [0145] to [0189] of WO2021/132674A can be applied.

### <Compound a Having Acid Group>

In the light absorption filter I according to the embodiment of the present invention, the wavelength selective absorption layer contains a compound A having an acid group (also simply referred to as a “compound A” in the present invention).

The acid group contained in the compound A is preferably a proton dissociable group having a pKa of 12 or less. Specific examples of the acid group include a carboxy group, a sulfonamide group (—S(═O)₂NH₂), a phosphonate group (—P(═O)(OH)₂), a phosphate group (—OP(═O)(OH)₂), a sulfo group, a phenolic hydroxyl group, and a sulfonyl imide group, where a carboxy group is preferable. It is noted that pKa means a negative common logarithm (−log Ka) of the acid dissociation constant (Ka) in water at 25° C., and it can be calculated in the same manner, except that in a calculation of the pKa of the compound B described later, a mixed solvent of water/methanol=50/50 (in terms of volume ratio) is changed to water.

The compound A may be a low-molecular-weight compound or a high-molecular-weight compound (hereinafter, also referred to as a “polymer”), where a polymer is preferable.

That is, the description that the compound A is a polymer means that the compound A is chemically bonded to a polymer that constitutes the resin contained in the wavelength selective absorption layer in the light absorption filter I according to the embodiment of the present invention.

In the present invention, in a case where the compound A is a low-molecular-weight compound, the molecular weight of the compound A is less than 5,000, and it is preferably 2,000 or less, more preferably 1,000 or less, still more preferably 500 or less, and particularly preferably 400 or less. The lower limit value thereof is not particularly limited. However, it is practically 100 or more, and it is preferably 200 or more.

In the present invention, in a case where the compound A is a polymer, the lower limit value of the weight-average molecular weight of the compound A is 5,000 or more, and it is preferably 10,000 or more and more preferably 15,000 or more from the viewpoint of physical properties of the optical filter. The upper limit value thereof is not particularly limited; however, it is preferably 500,000 or less, more preferably 200,000 or less, and still more preferably 150,000 or less from the viewpoint of solubility in a solvent.

In addition, a part or all of the acid groups contained in the compound A may or may not be anionized in the light absorption filter, and in the present invention, both an anionized acid group and a non-anionized acid group are also referred to as an acid group. That is, the compound A may or may not be anionized in the light absorption filter.

The compound A is preferably a compound having a carboxy group from the viewpoint of excellent film-forming properties of the light absorption filter.

The above-described compound having a carboxy group is more preferably a monomer containing a carboxy group (hereinafter, also referred to as a “carboxy group-containing monomer”) or a polymer containing a carboxy group (hereinafter, also referred to as a “carboxy group-containing polymer”), and it is more preferably a carboxy group-containing polymer from the viewpoint of the film-forming properties of the light absorption filter.

It is noted that a part or all of the carboxy groups (—COOH) contained in the carboxy group-containing monomer and the carboxy group-containing polymer may or may not be anionized in the light absorption filter, and both an anionized carboxy group (—COO—) and a non-anionized carboxy group are also referred to as a carboxy group.

That is, the carboxy group-containing polymer may or may not be anionized in the light absorption filter, and both an anionized carboxy group-containing polymer and a non-anionized carboxy group-containing polymer are also referred to as a polymer.

In the light absorption filter I according to the embodiment of the present invention, the content of the compound A in the wavelength selective absorption layer is preferably 1% by mass or more, more preferably 25% by mass or more, still more preferably 30% by mass or more, still preferably 45% by mass or more, and particularly preferably 50% by mass or more. The upper limit value of the content of the compound A is preferably less than 100% by mass, more preferably 99% by mass or less, and still more preferably 97% by mass or less.

Among the above, in a case where the compound A is a polymer, the content of the compound A in the wavelength selective absorption layer in the light absorption filter I according to the embodiment of the present invention is preferably 50% by mass or more and less than 100% by mass, more preferably 60% by mass or more and less than 100% by mass, and still more preferably 70% by mass or more and 100% by mass. The upper limit value thereof is also preferably 99% by mass or less, more preferably 97% by mass or less, still more preferably 95% by mass or less, and particularly preferably 90% by mass or less.

One kind of the compound A may be used alone, or two or more kinds thereof may be used in combination.

### (Carboxy Group-Containing Monomer)

Examples of the carboxy group-containing monomer include a polymerizable compound which contains a carboxy group and contains one or more (for example, 1 to 15) ethylenically unsaturated groups.

Examples of the ethylenically unsaturated group include a (meth)acryloyl group, a vinyl group, and a styryl group, and a (meth)acryloyl group is preferable.

It is noted that in a case where the ethylenically unsaturated group is a (meth)acryloyl group, a carbonyl bond in the (meth)acryloyl group and a carbonyl bond in the carboxy group may share one carbonyl bond.

From the viewpoint of more excellent film-forming properties, the carboxy group-containing monomer is preferably a bi- or higher functional monomer containing a carboxy group. The bi- or higher functional monomer means a polymerizable compound having 2 or more (for example, 2 to 15) ethylenically unsaturated groups in one molecule.

It suffices that the number of carboxy groups contained in the carboxy group-containing monomer is 1 or more, and the number thereof is, for example, preferably 1 to 8, more preferably 1 to 4, and still more preferably 1 or 2.

The carboxy group-containing monomer may further have, as an acid group, an acid group other than the carboxy group. Examples of the acid group other than the carboxy group include a phenolic hydroxyl group, a phosphate group, and a sulfonate group.

The bi- or higher functional monomer containing a carboxy group is not particularly limited and can be appropriately selected from commonly used compound compounds.

Examples of the bi- or higher functional monomer containing a carboxy group include, as product names, ARONIX M-520 and ARONIX M-510 (both manufactured by Toagosei Co., Ltd.).

In addition, examples of the bi- or higher functional monomer containing a carboxy group include a tri- or tetra-functional polymerizable compound having a carboxy group (a compound obtained by introducing a carboxy group into a pentaerythritol triacrylate and pentaerythritol tetraacrylate [PETA] skeleton (acid value=80 to 120 mgKOH/g)) and a penta- or hexa-functional polymerizable compound having a carboxy group (a compound obtained by introducing a carboxy group into a dipentaerythritol pentaacrylate and dipentaerythritol hexaacrylate [DPHA] skeleton (acid value=25 to 70 mgKOH/g)). In a case where the above-described tri- or higher functional monomer containing a carboxy group is used, from the viewpoint of more excellent film-forming properties, it is also preferable to use the bi- or higher functional monomer containing a carboxy group in combination.

Examples of the bi- or higher functional monomer containing a carboxy group and the bi- or higher functional monomer containing an acid group also include the polymerizable compounds having a carboxy group, which are described in paragraphs 0025 to 0030 of JP2004-239942A. The contents of this patent publication are incorporated in the present specification by reference.

### (Carboxy Group-Containing Polymer)

The carboxy group-containing polymer may further have, as an acid group, an acid group other than the carboxy group. Examples of the acid group other than the carboxy group include a phenolic hydroxyl group, a phosphate group, and a sulfonate group.

In a case where the carboxy group-containing polymer is a copolymer, the structure of the polymer may be a random polymer or a regular polymer such as a block.

### <<Constitutional Unit Having Carboxy Group>>

The carboxy group-containing polymer preferably has a constitutional unit having a carboxy group.

Examples of the constitutional unit having a carboxy group include a constitutional unit derived from (meth)acrylic acid, crotonic acid, itaconic acid, maleic acid, or fumaric acid. Among the above, a constitutional unit derived from (meth)acrylic acid is preferable from the viewpoint of an excellent decolorization property of the coloring agent.

In the carboxy group-containing polymer, the content of the constitutional unit having a carboxy group is preferably 1% to 100% by mole, more preferably 3% to 65% by mole, still more preferably 5% to 45% by mole, particularly preferably 10% to 45% by mole, and especially preferably 20% to 45% by mole in a case where the total of all the constitutional units of the carboxy group-containing polymer is set to 100% by mole.

One kind of the constitutional unit having a carboxy group may be used alone, or two or more kinds thereof may be used in combination.

### <<Constitutional Unit Having Aromatic Ring>>

It is also preferable that the carboxy group-containing polymer has a constitutional unit having an aromatic ring (preferably, an aromatic hydrocarbon ring) in addition to the above-described constitutional unit. Examples thereof include a constitutional unit derived from a (meth)acrylate having an aromatic ring (specifically, benzyl (meth)acrylate, phenethyl (meth)acrylate, phenoxyethyl (meth)acrylate, or the like).

In the carboxy group-containing polymer, the content of the constitutional unit having an aromatic ring is preferably 0% to 97% by mole, more preferably 0% to 95% by mole, still more preferably 0% to 90% by mole, and especially preferably 20% to 45% by mole in a case where the total of all the constitutional units of the carboxy group-containing polymer is set to 100% by mole.

One kind of the constitutional unit having an aromatic ring may be used alone, or two or more kinds thereof may be used in combination.

### <<Constitutional Unit Having Alicyclic Structure>>

It is also preferable that the carboxy group-containing polymer has a constitutional unit having an alicyclic structure in addition to the above-described constitutional unit.

Examples of the alicyclic structure include a tricyclo[5.2.1.0^{2,6}]decane ring structure (also referred to as tetrahydrodicyclopentadiene, where a monovalent group is dicyclopentanyl), a tricyclo[5.2.1.0^{2,6}]decane-3-ene ring structure (also referred to as 5,6-dihydrodicyclopentadiene, where a monovalent group is dicyclopentenyl), an isobornane ring structure (where a monovalent group is isobornyl), an adamantane ring structure, and a cyclohexane ring structure (where a monovalent group is cyclohexyl).

Examples of the constitutional unit having an alicyclic structure include a constitutional unit derived from a (meth)acrylate having an alicyclic structure. Specific examples thereof include a constitutional unit derived from dicyclopentanyl (meth)acrylate, dicyclopentenyl (meth)acrylate, isobornyl (meth)acrylate, adamantyl (meth)acrylate, cyclohexyl (meth)acrylate, or the like.

In the carboxy group-containing polymer, the content of the constitutional unit having an alicyclic structure is preferably 0% to 97% by mole, more preferably 0% to 95% by mole, still more preferably 0% to 90% by mole, and especially preferably 20% to 45% by mole in a case where the total of all the constitutional units of the carboxy group-containing polymer is set to 100% by mole.

One kind of the constitutional unit having an alicyclic structure may be used alone, or two or more kinds thereof may be used in combination.

### <<Another Constitutional Unit>>

The carboxy group-containing polymer may have another constitutional unit in addition to the above-described constitutional units.

Examples of the other constitutional unit include a constitutional unit derived from methyl (meth)acrylate.

In the carboxy group-containing polymer, the content of the other constitutional unit is preferably 0% to 70% by mole, more preferably 0% to 50% by mole, and still more preferably 0% to 20% by mole in a case where the total of all the constitutional units of the carboxy group-containing polymer is set to 100% by mole.

One kind of the other constitutional unit may be used alone, or two or more kinds thereof may be used in combination.

### <Compound B>

In the light absorption filter I according to the embodiment of the present invention, the wavelength selective absorption layer contains the compound B that forms a hydrogen bond with an acid group in the compound A and generates a radical upon ultraviolet irradiation (in the present invention, also simply referred to as the “compound B”).

The compound B is preferably a compound having such a structure that absorbs ultraviolet rays to be in an excited state, thereby having an increased basicity. In a case where the basicity of the compound B is increased in the excited state, it is possible to form a complex in which the acid group in the compound A interacts more strongly with the compound B, and it is possible to increase the efficiency of generating radicals.

A structure contained in the compound B, the structure forming a hydrogen bond with the acid group in the compound A, may be a whole structure of the compound B or may be a partial structure that constitutes a part of the compound B.

The compound B may be a high-molecular-weight compound (which means a compound having a molecular weight of 5,000 or more) or a low-molecular-weight compound (which means a compound having a molecular weight of less than 5,000), and it is preferably a low-molecular-weight compound.

The molecular weight of the compound B as a low-molecular-weight compound is less than 5,000, and it is preferably less than 1,000, more preferably 300 or less, and still more preferably 250 or less. The lower limit value thereof is not particularly limited; however, it is preferably 65 or more and more preferably 75 or more. Examples of the preferred range of the molecular weight of the compound B which is a low-molecular-weight compound include 65 to 300 and more preferably 75 to 250.

From the viewpoint that the molar absorption coefficient with respect to ultraviolet rays is large, the compound B is preferably an aromatic compound.

Here, the aromatic compound is a compound having one or more aromatic rings.

Only one aromatic ring may be present in the compound B, or a plurality of aromatic rings may be present therein. In a case where a plurality of aromatic rings is present, the aromatic rings may be present, for example, in the side chain or the like of the polymer that constitutes the resin.

The above-described aromatic ring may be any of an aromatic hydrocarbon ring or an aromatic heterocyclic ring, and it is preferable that the compound B has at least an aromatic heterocyclic ring. In a case of being an aromatic heterocyclic ring (also referred to as a heteroaromatic ring), it is a compound having one or more (for example, 1 to 4) heteroatoms (at least one or more among nitrogen atoms, oxygen atoms, sulfur atoms, and the like) as a ring member atom (ring-constituting atom) and preferably has one or more (for example, 1 to 4) nitrogen atoms as a ring member atom.

It is noted that an unsubstituted aromatic hydrocarbon ring does not have a function of forming a hydrogen bond with the acid group contained in the compound A and generating a radical upon ultraviolet irradiation, and thus it does not correspond to the compound B. In addition, an unsubstituted aromatic hydrocarbon ring in a form in which the unsubstituted aromatic hydrocarbon ring is bonded to the side chain of the polymer that constitutes the resin does not have a function of forming a hydrogen bond with the acid group contained in the compound A and generating a radical upon ultraviolet irradiation, and thus it does not correspond to the compound B.

The number of ring member atoms in the above-described aromatic ring is preferably 5 to 15.

Examples of the above-described aromatic ring include monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, and a quinazoline ring; and aromatic rings in which three rings are fused, such as an acridine ring, a phenanthridine ring, a phenanthroline ring, and a phenazine ring.

The above-described aromatic ring may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, and a nitro group. In addition, in a case where the above-described aromatic ring has two or more substituents, a plurality of substituents may be bonded to each other to form a non-aromatic ring.

In a case where a plurality of aromatic rings (for example, 2 to 5 aromatic rings) forms a series of aromatic ring structures bonded with a structure selected from a single bond, a carbonyl bond, and a multiple bond (for example, a vinylene group which may have a substituent, —C≡C—, —N═N—, and the like), the entire series of aromatic ring structures is regarded as one specific structure.

A series of aromatic ring structures in which the plurality of aromatic rings are bonded through a structure selected from a single bond, a carbonyl bond, or a multiple bond do not correspond to the above-described unsubstituted aromatic hydrocarbon ring, and do not correspond to the unsubstituted aromatic hydrocarbon ring in a form in which the unsubstituted aromatic hydrocarbon ring is bonded to a side chain of the polymer constituting the resin.

In addition, it is preferable that one or more of the aromatic rings constituting the series of aromatic ring structures are the above-described heteroaromatic rings.

Specific examples of the compound B include monocyclic aromatic compound such as a pyridine compound (pyridine or a pyridine derivative), a pyrazine compound (pyrazine or a pyrazine derivative), a pyrimidine compound (pyrimidine or a pyrimidine derivative), and a triazine compound (triazine or a triazine derivative); compounds in which two rings are fused to form an aromatic ring, such as a quinoline compound (quinoline or a quinoline derivative), an isoquinoline compound (isoquinoline or an isoquinoline derivative), a quinoxaline compound (quinoxaline or a quinoxaline derivative), and a quinazoline compound (quinazoline or a quinazoline derivative); and compounds in which three or more rings are fused to form an aromatic ring, such as an acridine compound (acridine or an acridine derivative), a phenanthridine compound (phenanthridine or a phenanthridine derivative), a phenanthroline compounds (phenanthroline or a phenanthroline derivative), and a phenazine compounds (phenazine or a phenazine derivative). In the specific examples of the compound B, the compound is used to have a meaning including not only the compound itself but a compound having a substituent (referred to as a “derivative”), including an unsubstituted compound in which a part of the structure has been changed, within a range where the effect of the present invention is not impaired.

It is presumed that this compound B forms a complex with the compound A and generates two molecules of radicals by the following mechanism upon ultraviolet irradiation.
1) The compound B in an excited state is generated by absorbing ultraviolet rays.
2) Positive holes move from the compound B in the excited state to the compound A in the ground state (the electrons of the compound A move to an orbital with lower energy in the two semi occupied molecular orbitals of the compound B in the excited state).
3) The movement of a proton from the compound A to the compound B generates a radical in which a hydrogen radical is loaded on the compound B and a radical in which a hydrogen radical is eliminated from the compound A.

In a case where the compound A is a compound having a carboxy group, the following reaction further occurs, and a radical is generated by a photodecarboxylation reaction.
4) Carbon dioxide is eliminated from the radical in which the hydrogen radical has been eliminated from the compound A.

Among the above, the compound B is preferably one or more among quinoline compounds (quinoline and a quinoline derivative) and isoquinoline compounds (isoquinoline and an isoquinoline derivative).

The substituent which may be contained in these compound is preferably an alkyl group, an aryl group, a halogen atom, an acyl group, an alkoxycarbonyl group, an arylcarbonyl group, a carbamoyl group, a hydroxy group, a cyano group, or a nitro group.

In a case where the compound B is a polymer, the compound B may be a polymer in which the above-described specific structure is bonded to a polymer main chain through a single bond or a linking group.

The compound B as a polymer is obtained by, for example, polymerizing a monomer having a heteroaromatic ring (specifically, a (meth)acrylate monomer having a heteroaromatic ring having a vinyl group and/or a specific structure (preferably, a heteroaromatic ring)). As necessary, copolymerization with another monomer may be carried out.

Specific examples of the compound B include quinoline, 2-methylquinoline, 4-methylquinoline, 2,4-dimethylquinoline, 2-methyl-4-phenylquinoline, isoquinoline, 1-methylisoquinoline, 3-methylisoquinoline, and 1-phenylisoquinoline.

From the viewpoint of achieving both the decolorization property of the ultraviolet irradiated portion and the durability of the coloring agent in the ultraviolet non-irradiated portion, the content of the compound B is preferably 0.1% to 50% by mass, more preferably 2.0% to 40% by mass, still more preferably 4% to 35% by mass, and particularly preferably 8% to 30% by mass, with respect to the total mass of the wavelength selective absorption layer in the light absorption filter I according to the embodiment of the present invention.

In addition, the pKaH (the pKa of the conjugate acid), which is an index of the basicity of the compound B, can be set to, for example, 2.0 or more and 13.0 or less, and it is preferably 2.0 or more and 7.0 or less, more preferably 3.0 or more and 6.0 or less, and still more preferably 4.3 or more and 5.5 or less, similarly, from the viewpoint of achieving both the decolorization property of the ultraviolet irradiated portion and the durability of the coloring agent in the ultraviolet non-irradiated portion.

In the present invention, the pKa means a negative common logarithm (−log Ka) of the acid dissociation constant (Ka) in a mixed solvent of water/methanol=50/50 (in terms of volume ratio) at 25° C. The pKa can be calculated by dropwise adding a 0.01 mol/L sodium hydroxide aqueous solution to a mixed solution of water/methanol=50/50 (in terms of volume ratio) of a measurement sample (a conjugate acid of the compound B) and reading the amount of the sodium hydroxide aqueous solution that has been dropwise added up to the half-equivalent point.

One kind of the compound B may be used alone, or two or more kinds thereof may be used in combination.

### <Photoradical Generator>

The wavelength selective absorption layer in the light absorption filter according to the embodiment of the present invention may contain a compound that generates a radical upon ultraviolet irradiation (hereinafter, also referred to as a “photoradical generator”). The wavelength selective absorption layer in the light absorption filter I according to the embodiment of the present invention may also contain a photoradical generator in addition to the above-described compound B.

The photoradical generator is not particularly limited as long as it is a compound that generates a radical upon ultraviolet irradiation and has a function of decolorizing the above-described coloring agent. It is noted that the radical generated may be a biradical in addition to the typical radical.

As the photoradical generator, a compound commonly used as a photoradical polymerization initiator a photoradical generator can be used without particular limitation, and examples thereof include an acetophenone generator, a benzoin generator, a benzophenone generator, a phosphine oxide generator, an oxime generator, a ketal generator, an anthraquinone generator, a thioxanthone generator, an azo compound generator, a peroxide generator, a disulfide generator, a lophine dimer generator, an onium salt generator, a borate salt generator, an active ester generator, an active halogen generator, an inorganic complex generator, and a coumarin generator. It is noted that an “XX generator” as the specific example of the photoradical generator may be individually referred to as an “XX compound” or “XX compounds”, and hereinafter, it is referred to as an “XX compound”.

Specific examples, preferred forms, commercially available products, and the like of the photoradical generator are respectively described as the specific examples, preferred forms, commercially available products, and the like of the photo-radical initiator in paragraphs [0133] to [0151] of JP2009-098658A, and these can be similarly used suitably in the present invention.

The photoradical generator is preferably a compound that generates a radical upon intramolecular cleavage or a compound that abstracts a hydrogen atom from a compound present in the vicinity thereof to generate a radical, and it is more preferably a compound that abstracts a hydrogen atom from a compound present in the vicinity thereof to generate a radical, from the viewpoint of further improving the decolorization rate.

The above-described compound that generates a radical upon intramolecular cleavage (hereinafter, also referred to as an “intramolecular cleavage type photoradical generator”) means a compound that generates a radical, where the compound absorbing light undergoes bonding cleavage in a homolytic manner.

Examples of the intramolecular cleavage type photoradical generator include an acetophenone compound, a benzoin compound, a phosphine oxide compound, an oxime compound, a ketal compound, an azo compound, a peroxide compound, a disulfide compound, an onium salt compound, a borate salt compound, an active ester compounds, an active halogen compound, an inorganic complex compound, and a coumarin compound. Among these, an acetophenone compound, a benzoin compound, or a phosphine oxide compound, which is a carbonyl compound, is preferable. The Norrish type I reaction is known as a photodecomposition reaction of an intramolecular cleavage type carbonyl compound, and this reaction can be referenced as a radical generation mechanism.

The above-described compound that abstracts a hydrogen atom from a compound present in the vicinity thereof to generate a radical (hereinafter, also referred to as a “hydrogen abstraction type photoradical generator”) means a carbonyl compound in an excited triplet state obtained upon light absorption that abstracts a hydrogen atom from a compound present in the vicinity thereof to generate a radical.

A carbonyl compound is known as the hydrogen abstraction type photoradical generator, and examples thereof include a benzophenone compound, an anthraquinone compound, and a thioxanthone compound. The Norrish type II reaction is known as a photodecomposition reaction of a hydrogen abstraction type carbonyl compound, and this reaction can be referenced as a radical generation mechanism.

Examples of the compound present in the vicinity include various components present in the light absorption filter, such as a resin, a coloring agent, and a radical generator.

The compound present in the vicinity becomes a compound having a radical by a hydrogen atom being abstracted therefrom. Since a coloring agent from which a hydrogen atom has been abstracted by the hydrogen abstraction type photoradical generator becomes an active compound having a radical, the coloring agent may be faded or decolorized through a reaction such as the decomposition of the coloring agent having the radical.

In addition, in a case where the hydrogen abstraction type photoradical generator abstracts a hydrogen atom in the molecule, a biradical is generated.

The hydrogen abstraction type photoradical generator is preferably a benzophenone compound from the viewpoint of the quantum yield of the hydrogen abstraction reaction.

Various examples of the photoradical generator are also described in “Latest UV Curing Technology”, TECHNICAL INFORMATION INSTITUTE CO. LTD., 1991, p. 159, and “Ultraviolet Curing System”, written by Kiyomi Kato, 1989, published by SOGO GIJUTSU CENTER, p. 65 to 148, which can be also suitably used in the present invention.

In the photoradical generator, the maximal absorption wavelength of the ultraviolet ray to be absorbed is preferably in a range of 250 to 400 nm, more preferably in a range of 240 to 400 nm, and still more preferably in a range of 270 to 400 nm.

In a case where the photoradical generator is a benzophenone compound, the wavelength of the absorption maximum attributed to the n-π* transition, which is located on the longest wavelength side, is preferably in a range of 260 to 400 nm and more preferably in a range of 285 to 345 nm. The wavelength of the absorption maximum attributed to π-π*, which is located on the second longest wavelength side, is preferably in a range of 240 to 380 nm and more preferably in a range of 270 to 330 nm. In a case where the absorption maximum wavelength is set in the above range, the light of a light source used at the time of exposure to the light absorption filter according to the embodiment of the present invention, such as a metal halide lamp, is absorbed well. On the other hand, in a case of being incorporated into a display device, the light absorption filter becomes difficult to absorb an ultraviolet ray incident from the outside, which makes it possible to achieve both the light resistance of the non-exposed portion and the decolorization property of the exposed portion.

Among the benzophenone compounds, examples of the photoradical generator having absorption in a longer wavelength range include an alkoxybenzophenone compound.

It is preferable that the maximal absorption wavelength of ultraviolet rays absorbed by the photoradical generator and the main absorption wavelength band of the squarine-based coloring agent represented by General Formula (1) are usually separated from each other by 30 nm or more. The upper limit value thereof is not particularly limited.

Examples of the commercially available photocleavage type photoradical generator include “Irgacure 651”, “Irgacure 184”, “Irgacure 819”, “Irgacure 907”, “Irgacure 1870” (a mixed initiator of CGI-403/Irgacure 184=7/3), “Irgacure 500”, “Irgacure 369”, “Irgacure 1173”, “Irgacure 2959”, “Irgacure 4265”, “Irgacure 4263”, “Irgacure 127”, or “OXE01”, all of which are product names, manufactured by BASF SE (formerly Ciba Specialty Chemicals Inc.); additionally, “Kayacure DETX-S”, “Kayacure BP-100”, “Kayacure BDMK”, “Kayacure CTX”, “Kayacure BMS”, “Kayacure 2-EAQ”, “Kayacure ABQ”, “Kayacure CPTX”, “Kayacure EPD”, “Kayacure ITX”, “Kayacure QTX”, “Kayacure BTC”, and “Kayacure MCA”, manufactured by Nippon Kayaku Co., Ltd.; and more additionally “Esacure (KIP100F, KB1, EB3, BP, X33, KTO46, KT37, KIP150, and TZT)” manufactured by Sartomer Company Inc. In addition, preferred examples thereof include a combination of two or more of these.

In a case where the wavelength selective absorption layer in the light absorption filter according to the embodiment of the present invention or the wavelength selective absorption layer in the light absorption filter I according to the embodiment of the present invention contains a radical generator, the preferred content and the preferred blending amount of the radical generator in the wavelength selective absorption layer are as follows, respectively.

The content of the radical generator (preferably, a photoradical generator) in the 100 parts by mass of the wavelength selective absorption layer is preferably 0.01 to 30 parts by mass, and more preferably 0.1 to 20 parts by mass.

From the viewpoint of further improving the decolorization rate, the blending amount of the radical generator (preferably, a photoradical generator) in the wavelength selective absorption layer is preferably 0.1 to 20 moles with respect to 1 mole of the squarine-based coloring agent represented by General Formula (1). The lower limit value thereof is more preferably 0.25 mole or more and still more preferably 0.50 mole or more. The upper limit value thereof is more preferably 17.5 mol or less and still more preferably 15 mol or less. The wavelength selective absorption layer may contain one kind of the radical generator (preferably a photoradical generator) or may contain two or more kinds thereof.

### <Another Component>

The wavelength selective absorption layer in the absorption filter according to the embodiment of the present invention may contain the above-described compound A having an acid group, the above-described compound B that forms a hydrogen bond with the acid group in the compound A, a photoradical generator, and the like, in addition to the above-described coloring agent and resin (matrix polymer), and may further contain an antifading agent, a matting agent, a leveling agent (a surfactant), and the like.

### <Antifading Agent>

The wavelength selective absorption layer in the light absorption filter according to the embodiment of the present invention may contain an antifading agent. It is preferable that the antifading agent does not inhibit the decolorization due to ultraviolet irradiation but has an effect of suppressing the decomposition of the coloring agent due to visible light.

The compound represented by General Formula (IV) below can be preferably used as the antifading agent.

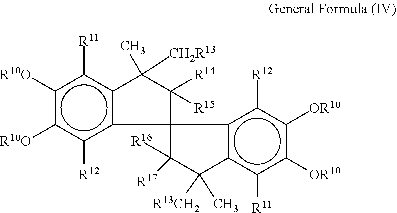

In Formula (IV), R¹⁰ represents an alkyl group, an alkenyl group, an aryl group, a heterocyclic group, or a group represented by R¹⁸CO—, R¹⁹SO₂—, or R²⁰NHCO—. Here, R¹⁸, R¹⁹, and R²⁰ each independently represent an alkyl group, an alkenyl group, an aryl group, or a heterocyclic group. R¹¹ and R¹² each independently represent a hydrogen atom, a halogen atom, an alkyl group, an alkenyl group, an alkoxy group, or an alkenyloxy group, and R¹³, R¹⁴, R¹⁵, R¹⁶, and R¹⁷ each independently represent a hydrogen atom, an alkyl group, an alkenyl group, or an aryl group.

However, the alkyl group in R¹⁰ to R²⁰ includes an aralkyl group.

The compound represented by General Formula (IV) is the same as the compound represented by General Formula (IV) described in [0215] to [0221] of WO2021/221122A. Therefore, for the description of each substituent in General Formula (IV) and the specific examples of the compound represented by General Formula (IV), the description of [0217] to [0221] of WO2021/221122A can be applied as it is.

As the antifading agent, the compound represented by General Formula [III] can also be preferably used.

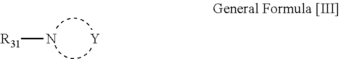

In General Formula [III], R₃₁ represents an aliphatic group or an aromatic group, and Y represents a non-metal atomic group necessary for forming a 5- to 7-membered ring with a nitrogen atom.

The compound represented by General Formula [III] is the same as the compound represented by General Formula [III] described in [0223] to [0227] of WO2021/221122A. Therefore, for the description of each substituent in General Formula [III] and the specific examples of the compound represented by General Formula [III], the description of [0225] to [0227] of WO2021/221122A can be applied as it is.

In addition, in addition to the above-described specific examples, specific examples of the compound represented by General Formula [III] above include exemplary compounds B-1 to B-65 described on pages 8 to 11 of JP1990-167543A (JP-H2-167543A), and exemplary compounds (1) to (120) described on pages 4 to 7 of JP1988-95439A (JP-S63-95439A).

The content of the antifading agent in the light absorption filter according to the embodiment of the present invention is preferably 1% to 15% by mass, more preferably 5% to 15% by mass, still more preferably 5% to 12.5% by mass, and particularly preferably 10% to 12.5% by mass in 100% by mass of the total mass of the wavelength selective absorption layer in the light absorption filter according to the embodiment of the present invention.

In a case where the antifading agent is contained within the above-described preferred range, the light absorption filter according to the embodiment of the present invention can improve the light resistance of the coloring agent (the dye) without causing side effects such as discoloration of the wavelength selective absorption layer.

### (Matting Agent)

In order to impart sliding properties and prevent blocking, fine particles may be added on the surface of the wavelength selective absorption layer in the light absorption filter according to the embodiment of the present invention, as long as the effects of the present invention are not impaired. As the fine particles, silica (silicon dioxide, SiO₂) of which the surface is coated with a hydrophobic group and which has an aspect of secondary particles is preferably used. As the fine particles, in addition to or instead of silica, fine particles of titanium dioxide, aluminum oxide, zirconium oxide, calcium carbonate, talc, clay, calcined kaolin, calcined calcium silicate, hydrated calcium silicate, aluminum silicate, magnesium silicate, and calcium phosphate may be used. Examples of the commercially available product of the fine particles include the R972 or NX90S (product name, both manufactured by Nippon Aerosil Co., Ltd.).

The fine particles function as a so-called matting agent, and the addition of the fine particles forms minute unevenness on the surface of the light absorption filter according to the embodiment of the present invention. Due to the unevenness, even in a case where the wavelength selective absorption layer in the light absorption filter according to the embodiment of the present invention and another film overlap with each other, the films do not stick to each other and sliding properties are secured.

In a case where the wavelength selective absorption layer in the light absorption filter according to the embodiment of the present invention contains a matting agent as fine particles, and in the fine irregularities due to the protrusions in which fine particles protrude from the filter surface, there are 10⁴/mm² or more of protrusions having a height of 30 nm or more, the effect of improving sliding properties and blocking properties is particularly large.

It is preferable to apply the matting agent (fine particles) particularly onto the surface layer in order to improve the blocking properties and the sliding properties. Examples of the method of applying fine particles onto the surface layer include methods such as multilayer casting and coating.

The content of the matting agent in the wavelength selective absorption layer in the light absorption filter according to the embodiment of the present invention is appropriately adjusted according to the intended purpose.

However, in the wavelength selective absorption layer in the light absorption filter according to the embodiment of the present invention, it is preferable that the above-described matting agent as fine particles are applied to the surface on which the adjacent layer described later is arranged, within a range where the effect of the present invention is not impaired.

### (Leveling Agent)

A leveling agent (a surfactant) can be appropriately mixed into the wavelength selective absorption layer in the light absorption filter according to the embodiment of the present invention. As the leveling agent, a commonly used compound can be used, and a fluorine-containing surfactant is particularly preferable. Specific examples thereof include the compounds described in paragraphs [0028] to [0056] of JP2001-330725A. In addition, as the commercially available product, MEGAFACE F (product name) series manufactured by DIC Corporation can also be used.

The content of the leveling agent in the wavelength selective absorption layer in the light absorption filter according to the embodiment of the present invention is appropriately adjusted according to the intended purpose.

The wavelength selective absorption layer in the light absorption filter according to the embodiment of the present invention may contain, in addition to each of the above-described components, a low-molecular plasticizer, an oligomer-based plasticizer, a retardation modifier, a deterioration preventing agent, a peeling accelerating agent, a peelability control resin component such as a peeling accelerator, an infrared absorbing agent, an antioxidant, a filler, a compatibilizer, and the like.

In addition, the wavelength selective absorption layer in the light absorption filter according to the embodiment of the present invention may contain a reaction accelerator or a reaction retarder described in paragraphs [0020] and [0021] of JP1997-286979A (JP-H09-286979A).

### <<Manufacturing Method for Wavelength Selective Absorption Layer>>

The wavelength selective absorption layer in the light absorption filter according to the embodiment of the present invention can be produced according to conventional method by a solution film-forming method, a melt extrusion method, or a method (coating method) of forming a coating layer on a base material film (support film) by any method, and stretching can also be appropriately combined. The wavelength selective absorption layer in the light absorption filter according to the embodiment of the present invention is preferably produced by a coating method.

For the solution film-forming method and melt extrusion method described above, the descriptions regarding the solution film-forming method and the melt extrusion method in [0197] to [0203] of WO2021/132674A can be applied as they are.

### (Coating Method)

In the coating method, a solution of a material of the wavelength selective absorption layer is applied onto a support film to form a coating layer. A mold release agent or the like may be appropriately applied onto the surface of the support film in advance in order to control the adhesiveness to the coating layer. The coating layer can be used by peeling off the support film after being laminated with another member while interposing an adhesive layer in a later step. Any adhesive can be appropriately used as the adhesive constituting the adhesive layer. The whole support film can be appropriately stretched in a state where a solution of a material of the wavelength selective absorption layer is applied onto the support film or in a state where a coating layer is laminated on the support film.

The solvent used for the solution of the material of the wavelength selective absorption layer can be appropriately selected from the viewpoint that the material of the wavelength selective absorption layer can be dissolved or dispersed, a uniform surface shape can be easily achieved during the coating step and drying step, liquid preservability can be secured, an appropriate saturated vapor pressure is provided.

### —Addition of Coloring Agent (Dye) and the Like—

The timing of adding the coloring agent to material of the wavelength selective absorption layer is not particularly limited as long as the coloring agent is added at the timing of film formation. For example, the coloring agent may be added at the timing when the matrix polymer (resin) is synthesized or may be mixed with the material of the wavelength selective absorption layer at the time of preparing the coating liquid for the material of the wavelength selective absorption layer. In addition, the same applies even in a case where the wavelength selective absorption layer contains the compound A, the compound B, and the like. It is noted that in a case where the compound A is bonded to the polymer that constitutes the resin, the compound A is added during the addition of the resin.

### —Support Film—

The support film to be used for forming the wavelength selective absorption layer according to the embodiment of the present invention by a coating method or the like preferably has a film thickness of 5 to 100 μm, more preferably 10 to 75 μm, and still more preferably 15 to 55 μm. In a case where the film thickness is equal to or larger than the above-described preferred lower limit value, sufficient mechanical strength can be easily secured, and failures such as curling, wrinkling, and buckling are less likely to occur. In addition, in a case where the film thickness is equal to or smaller than the preferred upper limit value, the surface pressure applied to the multi-layer film is easily adjusted to be in an appropriate range, and thus adhesion defect is less likely to occur in a case where a multi-layer film of the wavelength selective absorption layer and the support film is stored, for example, in a form of a long roll.

The surface energy of the support film is not particularly limited, and by adjusting the relationship between the surface energy of the material of the wavelength selective absorption layer or the coating solution and the surface energy of the surface of the support film on which the wavelength selective absorption layer is to be formed, the adhesive force between the wavelength selective absorption layer and the support film can be adjusted. In a case where the surface energy difference is reduced, the adhesive force tends to increase, and in a case where the surface energy difference is increased, the adhesive force tends to decrease, and thus the surface energy can be set appropriately.

In addition, the surface unevenness of the support film is not particularly limited; however, depending on the relationship between the surface energy of the wavelength selective absorption layer surface, the hardness, and the surface unevenness, and the surface energy and hardness of the support film opposite to the side on which the wavelength selective absorption layer is formed, the surface unevenness of the support film can be adjusted in order to prevent adhesion defect in a case where a multi-layer film of the wavelength selective absorption layer and the support film is stored, for example, in a form of a long roll. In a case where the surface unevenness is increased, adhesion defect tends to be suppressed, and in a case where the surface unevenness is reduced, the surface unevenness of the wavelength selective absorption layer tends to decrease and the haze of the wavelength selective absorption layer tends to be small. Thus, the surface unevenness can be set appropriately.

For such a support film, any material and film can be appropriately used. Specific examples of the material include a polyester-based polymer (including polyethylene terephthalate-based film), an olefin-based polymer, a cycloolefin-based polymer, a (meth)acrylic polymer, a cellulose-based polymer, and a polyamide-based polymer. In addition, a surface treatment can be appropriately carried out for the intended purpose of adjusting the surface properties of the support film. For example, a corona treatment, a room temperature plasma treatment, or a saponification treatment can be carried out to decrease the surface energy, and a silicone treatment, a fluorine treatment, an olefin treatment, or the like can be carried out to raise the surface energy.

### <Film Thickness of Wavelength Selective Absorption Layer>

The film thickness of the wavelength selective absorption layer is not particularly limited; however, it is preferably 1 to 18 μm, more preferably 1 to 12 μm, still more preferably 1 to 8 μm, and particularly preferably 2 to 8 μm. In a case where the film thickness is equal to or smaller than the above-described preferred upper limit value, the decrease in the degree of polarization due to the fluorescence emitted by a coloring agent (a dye) can be suppressed by adding the coloring agent to the thin film at a high concentration. In addition, the effect of the quencher is likely to be exhibited. On the other hand, in a case where the film thickness is equal to or larger than the above-described preferred lower limit value, it becomes easy to maintain the evenness of the in-plane absorbance.

In the present invention, the film thickness of 1 to 18 μm means that the thickness of the wavelength selective absorption layer is within a range of 1 to 18 μm in a case of being measured at any portion. The same applies to the film thicknesses of 1 to 12 μm and 2 to 8 m. The film thickness can be measured with an electronic micrometer manufactured by Anritsu Corporation.

### <Treatment of Wavelength Selective Absorption Layer>

The wavelength selective absorption layer may be subjected to a hydrophilic treatment by any of glow discharge treatment, corona discharge treatment, or alkali saponification treatment, and a corona discharge treatment is preferably used. It is also preferable to apply the method disclosed in JP1994-94915A (JP-H6-94915A) and JP1994-118232A (JP-H6-118232A).

As necessary, the obtained film may be subjected to a heat treatment step, a superheated steam contact step, an organic solvent contact step, or the like. In addition, a surface treatment may be appropriately carried out.

In addition, as a pressure-sensitive adhesive layer, a layer consisting of a pressure-sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description regarding the pressure-sensitive adhesive layer in the OLED display device described later can be applied.

### [Adjacent Layer]

The light absorption filter according to the embodiment of the present invention includes an adjacent layer arranged on at least one surface of the above-described wavelength selective absorption layer, and this adjacent layer contains an acidic or basic compound.

In a case where the light absorption filter according to the embodiment of the present invention or the optical filter according to the embodiment of the present invention is incorporated into a display device such as an organic electroluminescent display device, an inorganic electroluminescent display device, or a liquid crystal display device, the light absorption filter according to the embodiment of the present invention is preferable to have a form in which the above-described adjacent layer is provided at least a surface on an external light side (visible side) with respect to the above-described wavelength selective absorption layer. As a result, it is possible to further improve the light resistance and the heat resistance of the coloring agent in the wavelength selective absorption layer in the light absorption filter according to the embodiment of the present invention or the optical filter according to the embodiment of the present invention. The adjacent layer may be provided on only one surface of the wavelength selective absorption layer in the light absorption filter according to the embodiment of the present invention or the optical filter according to the embodiment of the present invention or may be provided on both surfaces thereof.

The above-described adjacent layer is not particularly limited. However, for example, a layer containing an acidic or basic compound may be provided, as the adjacent layer, on a layer (hereinafter, referred to as “the layer which is typically used in the display device”) which is typically used in a display device such as an organic electroluminescent display device, an inorganic electroluminescent display device, or a liquid crystal display device, which will be described later. For example, an acid or a basic compound is contained in a gas barrier layer or pressure-sensitive adhesive layer described below, the antireflection layer, the adhesive layer described above or a refractive index adjusting layer, whereby the above-described adjacent layer can be obtained.

In addition, a layer different from the layer that is typically used in the display device and is a layer containing an acid or a basic compound can be incorporated as the above-described adjacent layer.

### <Acidic or Basic Compound>

In the light absorption filter according to the embodiment of the present invention, it is considered that the acid or the basic compound (the acidic compound or basic compound) contained in the adjacent layer can adjust the pH of the wavelength selective absorption layer arranged on the adjacent layer and can improve the light resistance of the squarine-based coloring agent represented by General Formula (1) which is contained in the wavelength selective absorption layer.

### (Acidic Compound)

The acidic compound that can be contained in the adjacent layer is not particularly limited as long as it is a compound having an acid group and can improve the light resistance of the light absorption filter according to the embodiment of the present invention.

The embodiment in which the light resistance and the heat resistance of the light absorption filter according to the embodiment of the present invention are improved in a case where the adjacent layer in the light absorption filter according to the embodiment of the present invention contains an acidic compound includes for example, a form in which the above-described wavelength selective absorption layer exhibits basicity. Examples thereof include a light absorption filter in which the wavelength selective absorption layer in the light absorption filter according to the embodiment of the present invention contains the above-described compound B and this compound B is a compound exhibiting strong basicity (a compound in which a pKa of a conjugate acid is approximately 5.0 to 13.0; a compound in which a pKa of a conjugate acid is preferably 5.0 to 7.0, more preferably 5.0 to 6.0, and still more preferably 5.0 to 5.5 from the viewpoint of achieving both the decolorization property of the ultraviolet irradiated portion and the durability of the coloring agent in the ultraviolet non-irradiated portion.

The acid group contained in the acidic compound is preferably a proton dissociable group having a pKa of 12 or less. Specific examples of the acid group include a carboxy group, a sulfonamide group (—S(═O)₂NH₂), a phosphonate group (—P(═O)(OH)₂), a phosphate group (—OP(═O)(OH)₂), a sulfo group, a phenolic hydroxyl group, and a sulfonyl imide group, where a carboxy group or a sulfo group is preferable. It is noted that pKa has the same meaning as pKa in the compound A described above.

For the acidic compound, for example, the description related to the compound A having an acid group described above can be preferably applied.

In the present invention, a polymer (hereinafter, referred to as an “acidic polymer”) obtained by linking the acid group of the acidic compound is linked to a polymer may be used, and preferred examples thereof include a polymer containing a constitutional unit having an acid group. As the acidic polymer, polyacrylic acid, polymethacrylic acid, polystyrene sulfonic acid, or the like can be preferably used.

The content of the acidic compound in the adjacent layer is not particularly limited; however, it can be adjusted so that excellent light resistance and excellent heat resistance can be obtained.

### (Basic Compound)

The basic compound that can be contained in the adjacent layer is not particularly limited as long as it is a compound that exhibits basicity and can improve the light resistance of the light absorption filter according to the embodiment of the present invention.

The embodiment in which the light resistance and the heat resistance of the light absorption filter according to the embodiment of the present invention are improved in a case where the adjacent layer in the light absorption filter according to the embodiment of the present invention contains a basic compound includes a form in which the above-described wavelength selective absorption layer exhibits an acidity, and specific examples thereof include a light absorption filter in which the wavelength selective absorption layer in the light absorption filter according to the embodiment of the present invention contains the above-described compound A. In addition, as shown in the comparison between the light absorption filters No. P106 and No. c23 which have used polybenzyl methacrylate as a resin 2 in Examples described later, the light resistance and the heat resistance of the light absorption filter according to the embodiment of the present invention are improved by containing a basic compound in the adjacent layer in the light absorption filter according to the embodiment of the present invention even in a case where the wavelength selective absorption layer itself in the light absorption filter according to the embodiment of the present invention is neutral. Specifically, the case where the wavelength selective absorption layer itself is neutral includes a form in which the wavelength selective absorption layer does not contain any of the above-described compound A and the above-described compound B.

The above-described basic compound may be organic or may be inorganic, and it is preferably an organic basic compound and more preferably an organic basic compound (a nitrogen-containing basic compound) containing a nitrogen atom.

The organic basic compound is preferably a compound having a pKaH (pKa of a conjugate acid) of 4 or more. The upper limit value of the pKa of the conjugate acid is not particularly limited; however, it is practically 13 or less. It is noted that pKa has the same meaning as pKa in the compound B described above.

Preferred examples of the nitrogen-containing basic compound having a pKaH (pKa of a conjugate acid) of 4 or more include a compound represented by General Formula (A) and a compound having a structure represented by any of Formulae (B) to (D) or a structure represented by General Formula (E). It is noted that a structure represented by any of Formulae (B) to (D) or a structure represented by General Formula (E) may be included in the compound as a part of a ring structure.

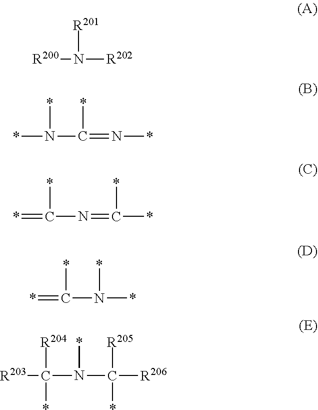

In Formula (A), R²⁰⁰ to R²⁰² represent a hydrogen atom, an alkyl group or a cycloalkyl group having 1 to 20 carbon atoms, or an aryl group having 6 to 20 carbon atoms. It is noted that R²⁰¹ and R²⁰² may be bonded to each other to form a ring.

The alkyl group, the cycloalkyl group, and the aryl group, which can be adopted as R²⁰⁰ to R²⁰² may be unsubstituted or may have a substituent. Preferred examples of the alkyl group and the cycloalkyl group which have a substituent include an aminoalkyl group having 1 to 20 carbon atoms and an aminocycloalkyl group as well as a hydroxyalkyl group having 1 to 20 carbon atoms.

In Formula (E), R²⁰³ to R²⁰⁶ represent an alkyl group having 1 to 6 carbon atoms or a cycloalkyl group.

* represents a bonding site.

Preferred specific examples of the compound represented by General Formula (A) in which the pKaH (the pKa of the conjugate acid) is 4 or more, or the compound having the structure represented by any of Formulae (B) to (D) or the structure represented by General Formula (E) include guanidine, aminopyridine, an aminoalkyl pyridine, aminopyrrolidine, indazole, imidazole, pyrazole, pyrazine, pyrimidine, purine, imidazoline, pyrazoline, piperazine, aminomorpholine, and aminomorpholine. Preferred examples of the substituent which may be contained in these compounds include an amino group, an alkylamino group, an aminoaryl group, an arylamino group, an alkyl group (particularly, an aminoalkyl group as a substituted alkyl group), an alkoxy group, an acyl group, an acyloxy group, an aryl group, an aryloxy group, a nitro group, a hydroxyl group, and a cyano group.

Among these, examples of the particularly preferable compound include guanidine, 1,1-dimethylguanidine, 1,1,3,3,-tetramethylguanidine, imidazole, 2-methylimidazole, 4-methylimidazole, N-methylimidazole, 2-phenylimidazole, 4,5-diphenylimidazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine, and N-(2-aminoethyl)morpholine. However, examples thereof are not limited thereto.

In the present invention, the above-described organic basic compound may be bonded to a polymer, and preferred examples thereof include a polymer (hereinafter, referred to as a “basic polymer”) containing a constitutional unit to which an organic basic compound is bonded or a constitutional unit obtained from an organic basic compound. Specific examples of the above-described basic polymer include polyethyleneimine, polyamine, and polyvinylpyridine, among which polyethyleneimine or polyamine is preferable. The pKaH (pKa of the conjugate acid) of any basic polymers described as specific examples is 4 or more.

As the polyethyleneimine in the present invention, it is possible to preferably use, for example, EPOMIN SP-200, EPOMIN HM-2000, EPOMIN S-1000, and EPOMIN S-3000, all of which are product names and manufactured by Nippon Shokubai Co., Ltd.), and Polyethyleneimine 10000 and Polyethyleneimine 70000, which are manufactured by Junsei Chemical Co., Ltd.) In addition, polyethyleneimine manufactured by FUJIFILM Wako Pure Chemical Corporation can also be preferably used.

In addition, as the polyamine in the present invention, it is possible to preferably use for example, PVAM0570B, PVAM0595B, and PVDL, all of which are product names and manufactured by Mitsubishi Chemical Corporation, and PAA-1% C, PAA-25, PAA-50, PAA-100, PAA-1222, PAA-U5000, PAA-N5000, PAS-21, and PAA-D11, which are manufactured by NITTOBO MEDICAL CO., LTD.

The content of the basic compound in the above-described adjacent layer is preferably 0.5 parts by mass or more, more preferably 0.75 parts by mass or more, still more preferably 1.0 parts by mass or more, and particularly preferably 1.5 parts by mass or more with respect to a total of 100 parts by mass of components other than the basic compound constituting the adjacent layer. The upper limit value thereof is preferably 45 parts by mass or less, more preferably 30 parts by mass or less, still more preferably 20 parts by mass or less, and particularly preferably 15 parts by mass or less. The preferred range of the content of the basic compound in the adjacent layer includes, for example, 0.5 to 45 parts by mass, more preferably 0.75 to 30 parts by mass, still more preferably 1.0 to 20 parts by mass, and particularly preferably 1.5 to 15 parts by mass with respect to a total of 100 parts by mass of components other than the basic compound constituting the adjacent layer. In a case where the content of the basic compound in the adjacent layer is adjusted, the light resistance and the heat resistance can be improved in a well-balanced manner.

### <Film Thickness of Light Absorption Filter According to Embodiment of Present Invention>

The film thickness of the light absorption filter according to the embodiment of the present invention is not particularly limited, and it is preferably 1 to 18 μm, more preferably 1 to 12 μm, and still more preferably 2 to 8 μm. In a case where the film thickness is equal to or smaller than the above-described preferred upper limit value, the decrease in the degree of polarization due to the fluorescence emitted by a coloring agent (a dye) can be suppressed by adding the coloring agent to the thin film at a high concentration. In addition, the effect of the quencher is likely to be exhibited. On the other hand, in a case where the film thickness is equal to or larger than the above-described preferred lower limit value, it becomes easy to maintain the evenness of the in-plane absorbance.

In the present invention, the film thickness of 1 to 18 μm means that the thickness of the light absorption filter according to the embodiment of the present invention is within a range of 1 to 18 μm in a case of being measured at any portion. The same applies to the film thicknesses of 1 to 12 μm and 2 to 8 μm. The film thickness can be measured with an electronic micrometer manufactured by Anritsu Corporation.

### <Absorbance of Light Absorption Filter of According to Embodiment According to Embodiment of Present Invention>

In the light absorption filter according to the embodiment of the present invention, the absorbance at the maximal absorption wavelength at which the squarine-based coloring agent represented by General Formula (1) exhibits the highest absorbance (hereinafter, also simply referred to as “Ab (λₘₐₓ)”) is preferably 0.3 or more, more preferably 0.5 or more, and still more preferably 0.7 or more.

However, the absorbance of the light absorption filter according to the embodiment of the present invention can be adjusted by the kind, the adding amount, or the film thickness of the coloring agent contained in the wavelength selective absorption layer in the light absorption filter according to the embodiment of the present invention. In addition, even in a case where the light absorption filter according to the embodiment of the present invention contains a coloring agent other than the squarine-based coloring agent represented by General Formula (1), it is preferable that the absorbance at the maximal absorption wavelength at which the coloring agent to be contained exhibits the highest absorbance at a wavelength of 400 to 700 nm is within the above-described preferred range of Ab (λₘₐₓ) described above.

In a case where the light absorption filter according to the embodiment of the present invention has a decolorization property, the decolorization rate of the light absorption filter according to the embodiment of the present invention due to ultraviolet irradiation is preferably 35% or more, more preferably 45% or more, and still more preferably 55% or more, among which 70% or more is particularly preferable. The upper limit value thereof is not particularly limited, and it is preferably 100%.

The decolorization rate is calculated according to the following expression using the values of Ab (λₘₐₓ) before and after the ultraviolet irradiation test.

$$Decolorization rate ( \% ) = 100 - ( Ab ( {λ}_{max} ) after ultraviolet irradiation / Ab ( {λ}_{max} ) before ultraviolet irradiation ) \times 100 \%$$

Here, in the ultraviolet irradiation test, an ultra-high pressure mercury lamp (manufactured by HOYA Corporation, product name: UL750) is used under atmospheric pressure (101.33 kPa) to irradiate the light absorption filter with ultraviolet rays at an illuminance of 100 mW/cm² and an irradiation amount of 1,000 mJ/cm² at room temperature (25° C.).

The absorbance, the ultraviolet irradiation test, and the decolorization rate can be measured and calculated for the light absorption filter according to the embodiment of the present invention according to the methods described in Examples.

In addition, in a case where the light absorption filter according to the embodiment of the present invention has a decolorization property, it is preferable that the light absorption filter according to the embodiment of the present invention hardly causes absorption (secondary absorption) derived from a new coloration structure associated with the decomposition of the coloring agent.

For example, the presence or absence of the absorption derived from the new coloration structure associated with the decomposition of the coloring agent can be checked based on the ratio of the absorbance at a specific wavelength to the above Ab (λₘₐₓ). As the specific wavelength, a wavelength at which the coloring agent before ultraviolet irradiation seldom exhibits absorption but new absorption due to the decomposition of the coloring agent is observed is selected.

As a specific example, as described in Examples described later, the presence or absence of the absorption derived from a new coloration structure associated with the decomposition of the coloring agent can be checked based on the ratio of the absorbance at a wavelength of 450 nm to the above Ab (λₘₐₓ) (hereinafter, also simply referred to as “Ab (450)”). That is, it is meant that the smaller the value obtained by subtracting the ratio of the following (I) from the ratio of the following (II), the less frequently the absorption derived from the new coloration structure associated with the decomposition of the coloring agent occurs. This value is preferably less than 8.5%, more preferably 7.0% or less, and still more preferably 5.0% or less. The lower limit value thereof is not particularly limited; however, it is practically −10% or more and preferably −6% or more from the viewpoint of making valid the evaluation related to the presence or absence of the secondary absorption associated with the decomposition of the coloring agent.

$$Ab ( 450 ) before ultraviolet irradiation \text{} / Ab ( {λ}_{max} ) \times 100 \% before ultraviolet irradiation \qquad ( I )$$

$$Ab ( 450 ) after ultraviolet irradiation / \text{} Ab \text{} ( {λ}_{max} ) before ultraviolet irradiation \times 100 \% \qquad ( II )$$

For the checking of the presence or absence of the absorption derived from the new coloration structure associated with the decomposition of the coloring agent, the calculation can be carried out based on Ab (λₘₐₓ) and Ab (450) which are measured according to the method described in Examples.

The light absorption filter according to the embodiment of the present invention can exhibit an excellent decolorization property in a case where both the above-described decolorization rate and the above-described value for checking the presence or absence of the absorption derived from the new coloration structure associated with the decomposition of the coloring agent satisfy a preferred range.

The light absorptive portion having a light absorption effect in the optical filter according to the embodiment of the present invention preferably satisfies the above description of Ab (λₘₐₓ) related to the light absorption filter according to the embodiment of the present invention.

### <Optical Functional Film>

The light absorption filter according to the embodiment of the present invention may appropriately have the gas barrier layer or any optical functional film within a range where the effect of the present invention is not impaired.

The optional optical functional film is not particularly limited in terms of any of the optical properties and the materials, and a film containing (or containing as a main component) at least any of a cellulose ester resin, an acrylic resin, a cyclic olefin resin, and a polyethylene terephthalate resin can be preferably used. It is noted that an optically isotropic film or an optically anisotropic phase difference film may be used.

For the above optional optical functional films, for example, Fujitac TD80UL (manufactured by FUJIFILM Corporation) or the like can be used as a film containing a cellulose ester resin.

Regarding the optional optical functional film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optically functional film containing a (meth)acrylic resin having a glutaric anhydride unit described in JP2009-139754A can be used.

In addition, regarding the optional optical functional films, as those containing a cyclic olefin resin, cyclic olefin-based resin film described in paragraphs [0029] and subsequent paragraphs of JP2009-237376A, and cyclic olefin resin film containing an additive reducing Rth described in JP4881827B, and JP2008-063536A can be used.

### <Gas Barrier Layer>

The light absorption filter according to the embodiment of the present invention may have a gas barrier layer on at least one surface. In a case where the light absorption filter according to the embodiment of the present invention has a gas barrier layer, the light absorption filter according to the embodiment of the present invention can be made to be a light absorption filter that achieves both an excellent decolorization property and excellent light resistance and can be suitably used in the production of an optical filter described later.

The material that forms the gas barrier layer is not particularly limited, and examples thereof include an organic material (preferably a crystalline resin) such as polyvinyl alcohol or polyvinylidene chloride, an organic-inorganic hybrid material such as a sol-gel material, and an inorganic material such as SiO₂, SiOₓ, or SiON, SiNₓ, or Al₂O₃. The gas barrier layer may be a single layer or a multi-layer. In the case of a multi-layer, examples thereof include configurations such as an inorganic dielectric multi-layer film and a multi-layer film obtained by alternately laminating organic materials and inorganic materials.

In a case where the light absorption filter according to the embodiment of the present invention includes the gas barrier layer at least on a surface that comes into contact with air in a case where the light absorption filter according to the embodiment of the present invention is used, it is possible to suppress a decrease in the absorption intensity of the coloring agent in the light absorption filter according to the embodiment of the present invention. As long as the gas barrier layer is provided at an interface of the light absorption filter according to the embodiment of the present invention in contact with air, the gas barrier layer may be provided on only one surface of the light absorption filter according to the embodiment of the present invention, or may be provided on both surfaces.

Among the above, in a case of a configuration in which the gas barrier layer contains a crystalline resin, the gas barrier layer contains a crystalline resin, and it is preferable that the thickness of the layer is 0.1 μm to 10 μm and the oxygen permeability of the layer is 60 cc/m²·day·atm or less.

In the gas barrier layer, the “crystalline resin” is a resin having a melting point that undergoes a phase transition from a crystal to a liquid in a case where the temperature is raised, and it can impart gas barrier properties related to oxygen gas to the gas barrier layer.

### (Crystalline Resin)

The crystalline resin contained in the gas barrier layer is a crystalline resin having gas barrier properties, and it can be used without particular limitation as long as a desired oxygen permeability can be imparted to the gas barrier layer.

Examples of the crystalline resin include polyvinyl alcohol and polyvinylidene chloride, and the polyvinyl alcohol is preferable from the viewpoint that a crystalline portion can effectively suppress the permeation of gas.

The polyvinyl alcohol may be modified or may not be modified. Examples of the modified polyvinyl alcohol include modified polyvinyl alcohol into which a group such as an acetoacetyl group and a carboxyl group is introduced.

The saponification degree of the polyvinyl alcohol is preferably 80.0% by mole or more, more preferably 90.0% by mole or more, still more preferably 97.0% by mole or more, and particularly preferably 98.0% by mole or more, from the viewpoint of further enhancing the oxygen gas barrier properties. The upper limit value thereof is not particularly limited; however, it is practically 99.99% by mole or less. The saponification degree of the polyvinyl alcohol is a value calculated based on the method described in JIS K 6726 1994.

The gas barrier layer may contain any component generally contained in the gas barrier layer within a range where the effect of the present invention is not impaired. For example, in addition to the above crystalline resin, organic-inorganic hybrid materials such as an amorphous resin material and a sol-gel material, and inorganic materials such as SiO₂, SiOₓ, SiON, SiNₓ, and Al₂O₃ may be contained.

Further, the gas barrier layer may contain a solvent such as water and an organic solvent derived from a manufacturing step within a range where the effect of the present invention is not impaired.

The content of the crystalline resin in the gas barrier layer is, for example, preferably 90% by mass or more and more preferably 95% by mass or more in 100% by mass of the total mass of the gas barrier layer. The upper limit value thereof is not particularly limited, and it can be set to 100% by mass.

The oxygen permeability of the gas barrier layer is preferably 60 cc/m²·day·atm or less, more preferably 50 cc/m²·day·atm or less, still more preferably 30 cc/m²·day·atm or less, and particularly preferably 10 cc/m²·day·atm or less. Among the above, it is preferably 5 cc/m²·day·atm or less and most preferably 1 cc/m²·day·atm or less. The practical lower limit value thereof is 0.001 cc/m²·day·atm or more, and it is preferably, for example, more than 0.05 cc/m²·day·atm. In a case where the oxygen permeability is within the above-described preferred range, the light resistance can be further improved.

The oxygen permeability of the gas barrier layer is a value measured based on the gas permeability test method based on JIS K 7126-2 2006. As the measuring device, for example, an oxygen permeability measuring device OX-TRAN2/21 (product name) manufactured by MOCON can be used. The measurement conditions are set to a temperature of 25° C. and a relative humidity of 50%.

For the oxygen permeability, (fm)/(s·Pa) can be used as the SI unit. It is possible to carry out the conversion by (1 fm)/(s·Pa)=8.752 (cc)/(m²·day·atm). fm is read as femtometer and represents 1 fm=10⁻¹⁵ μm.

The thickness of the gas barrier layer is preferably 0.5 μm to 5 μm, and more preferably 1.0 μm to 4.0 μm, from the viewpoint of further improving the light resistance.

The thickness of the gas barrier layer is measured by a method of capturing a cross-sectional image using a field emission scanning electron microscope S-4800 (product name) manufactured by Hitachi High-Tech Corporation.

The degree of crystallinity of the crystalline resin contained in the gas barrier layer is preferably 25% or more, more preferably 40% or more, and still more preferably 45% or more. The upper limit value thereof is not particularly limited, and it is practically 55% or less and preferably 50% or less.

The degree of crystallinity of the crystalline resin contained in the gas barrier layer is a value measured and calculated according to the following method based on the method described in J. Appl. Pol. Sci., 81, 762 (2001).

Using a differential scanning calorimeter (DSC), a temperature of a sample peeled from the gas barrier layer is raised at 10° C./min over the range of 20° C. to 260° C., and a heat of fusion 1 is measured. Further, as a heat of fusion 2 of the perfect crystal, the value described in J. Appl. Pol. Sci., 81, 762 (2001) is used. Using the obtained heat of fusion 1 and heat of fusion 2, the degree of crystallinity is calculated according to the following expression.

$$[ Degree of crystallinity ( \% ) ] = ( [ heat of fusion 1 ] / [ heat of fusion 2 ] ) \times 100$$

The heat of fusion 1 and heat of fusion 2 may have the same unit, which is generally Jg⁻¹.

### <Manufacturing Method for Gas Barrier Layer>

The method of forming the gas barrier layer is not particularly limited, and examples thereof include a producing method according to a conventional method according to a casting method such as spin coating or slit coating, for example, in a case of an organic material. In addition, examples thereof can include a method of bonding a commercially available resin gas barrier film or a resin gas barrier film produced in advance to the light absorption filter according to the embodiment of the present invention. In addition, in a case of an inorganic material, examples thereof include a plasma enhanced chemical vapor deposition (CVD) method, a sputtering method, and a vapor deposition method.

In a case where the above-described gas barrier layer is provided in the light absorption filter according to the embodiment of the present invention, for example, a method of directly producing the above-described gas barrier layer on the light absorption filter according to the embodiment of the present invention produced according to the above-described production method is included. In this case, it is also preferable to apply a corona treatment to the surface of the light absorption filter according to the embodiment of the present invention to which the gas barrier layer is provided.

In addition, in a case where the above-described optional optical functional film is provided, it is also preferable to carry out bonding while interposing a pressure-sensitive adhesive layer. For example, it is also preferable that a gas barrier layer is provided on the light absorption filter according to the embodiment of the present invention and then bonded to an optical functional film while interposing a pressure-sensitive adhesive layer.

In a case of being provided as an adjacent layer in the light absorption filter according to the embodiment of the present invention, the above-described gas barrier layer or optical functional film can be provided in the same manner as described above except that it is provided to serve as a gas barrier layer containing an acid or a basic compound with respect to the wavelength selective absorption layer in the light absorption filter according to the embodiment of the present invention.

### [Optical Filter]

In a case where the light absorption filter according to the embodiment of the present invention has a decolorization property, the optical filter according to the embodiment of the present invention is obtained by subjecting the light absorption filter according to the embodiment of the present invention to mask exposure with ultraviolet irradiation.

Examples of the light absorption filter having a decolorization property among the light absorption filters according to the embodiment of the present invention include a light absorption filter containing the above-described radical generator in the wavelength selective absorption layer and a light absorption filter I in which the wavelength selective absorption layer contains the above-described compound A that has an acid group and the above-described compound B that forms a hydrogen bond with the acid group contained in the compound A and generates a radical upon ultraviolet irradiation.

In a case of being simply referred to as the light absorption filter according to the embodiment of the present invention in the following explanatory description related to the optical filter and the explanatory description related to the manufacturing method for the optical filter, it means the light absorption filter having a decolorization property according to the embodiment of the present invention having the colorability.

The wavelength selective absorption layer in the optical filter according to the embodiment of the present invention has a light absorptive portion having a light absorption effect and a portion in which light absorption absorbability has been eliminated (an absorbability-eliminated portion) in response to a mask exposure pattern (hereinafter, also referred to as a “mask pattern”).

That is, in a case where the light absorption filter according to the embodiment of the present invention is subjected to mask exposure by ultraviolet irradiation, the masked portion of the wavelength selective absorption layer in the light absorption filter according to the embodiment of the present invention is not exposed and present as a light absorptive portion having a light absorption effect, whereas the unmasked portion is exposed and becomes an absorbability-eliminated portion.

The light absorptive portion can exhibit a desired absorbance.

In addition, the absorbability-eliminated portion can exhibit optical characteristics close to colorlessness since the wavelength selective absorption layer in the light absorption filter according to the embodiment of the present invention exhibits an excellent decolorization rate and moreover, secondary absorption seldom occurs in association with the decomposition of the coloring agent.

### <Manufacturing Method for Optical Filter>

The optical filter according to the embodiment of the present invention can be obtained by irradiating the light absorption filter according to the embodiment of the present invention with an ultraviolet ray to carry out mask exposure.

The mask pattern can be appropriately adjusted so that the optical filter according to the embodiment of the present invention having a desired pattern consisting of a light absorptive portion and a light absorbability-eliminated portion can be obtained.

The conditions of ultraviolet irradiation can be appropriately adjusted so that the optical filter according to the embodiment of the present invention having a light absorbability-eliminated portion can be obtained. For example, the ultraviolet irradiation can be carried out under atmospheric pressure (101.33 kPa) regarding the pressure condition and can be carried out under a mild temperature condition regarding the temperature condition without carrying out heating at room temperature (10° C. to 30° C.) or the like, the lamp output can be set to 80 to 320 W/cm, and an air-cooled metal halide lamp, a mercury lamp such as an ultra-high pressure mercury lamp, or the like can be used as a lamp to be used. In addition, the irradiation amount can be set to 200 to 1,000 mJ/cm².

The optical filter according to the embodiment of the present invention may have an optical functional film described in the light absorption filter according to the embodiment of the present invention.

In addition, the optical filter according to the embodiment of the present invention may have a layer containing an ultraviolet absorbing agent. As the ultraviolet absorbing agent, a commonly used compound can be used without particular limitation, and examples thereof include an ultraviolet absorbing agent in the ultraviolet absorbing layer described later. The resin constituting the layer containing the ultraviolet absorbing agent is also not particularly limited, and examples thereof include a resin in the ultraviolet absorbing layer described later.

The content of the ultraviolet absorbing agent in the layer containing the ultraviolet absorbing agent is appropriately adjusted according to the intended purpose.

The optical filter according to the embodiment of the present invention can be used for display devices such as an organic electroluminescent display device, an inorganic electroluminescent display device, and a liquid crystal display device. It is preferable that, in any case of being used in the above-described display devices, the optical filter according to the embodiment of the present invention is disposed such that an adjacent layer containing an acid or a basic compound is located on the external light with respect to the wavelength selective absorption layer.

### [OLED Display Device]

The organic electroluminescent display device according to the embodiment of the present invention (referred to as an organic electroluminescence (EL) display device or an organic light emitting diode (OLED) display device, and abbreviated as an OLED display device in the present invention) includes the optical filter according to the embodiment of the present invention.

As another configuration of the OLED display device according to the embodiment of the present invention, the configuration of the generally used OLED display device can be used without particular limitation, as long as the optical filter according to the embodiment of the present invention is included. The configuration example of the OLED display device according to the embodiment of the present invention is not particularly limited, and examples thereof include a display device including glass, a layer containing a thin film transistor (TFT), an OLED display element, a barrier film, a color filter, glass, a pressure-sensitive adhesive layer, the optical filter according to the embodiment of the present invention, and a surface film, in order from the opposite side to external light.

The OLED display element has a configuration in which an anode electrode, a light emitting layer, and a cathode electrode are laminated in this order. In addition to the light emitting layer, a hole injection layer, a hole transport layer, an electron transport layer, an electron injection layer, and the like are included between the anode electrode and the cathode electrode. In addition, for example, the description in JP2014-132522A can also be referenced.

In addition, as the color filter, in addition to a typical color filter, a color filter in which quantum dots are laminated can also be used.

A resin film can be used instead of the above glass.

### <Pressure-Sensitive Adhesive Layer>

In the OLED display device according to the embodiment of the present invention, a surface of the optical filter according to the embodiment of the present invention on the external light side may be bonded to an optical functional film having an antireflection layer or the like with a pressure-sensitive adhesive layer being interposed. In addition, it is preferable that a surface of the optical filter according to the embodiment of the present invention, which is positioned opposite to the side of the external light, is bonded to the glass (the base material) with a pressure-sensitive adhesive layer being interposed.

For the pressure-sensitive adhesive layer, the descriptions related to the pressure-sensitive adhesive layer and the forming method in the OLED display device, which are described in [0239] to [0290] of WO2021/132674A, can be applied as they are.

It is noted that the pressure-sensitive adhesive composition described in WO2021/132674A preferably contains the above-described ultraviolet absorbing agent from the viewpoint of the light resistance of the light absorption filter.

### <Base Material>

In the OLED display device according to the embodiment of the present invention, a surface of the optical filter according to the embodiment of the present invention, which is positioned on the external light side, may be bonded to any optical functional film with a pressure-sensitive adhesive layer being interposed. In addition, it is preferable that a surface of the optical filter according to the embodiment of the present invention, which is positioned opposite to the side of the external light, is bonded to the glass (the base material) with a pressure-sensitive adhesive layer being interposed.

Examples of the optical functional film in which the pressure sensitive adhesive or the like may be bonded to the base material include the above-described optical functional film.

The method of forming the adhesive layer is not particularly limited, and for example, a method of applying the pressure-sensitive adhesive composition to the light absorption filter according to the embodiment of the present invention by a usual means such as a bar coater, drying, and curing the pressure-sensitive adhesive composition; a method of applying the pressure-sensitive adhesive composition first to the surface of a peelable base material, and drying the composition, and then transferring the pressure-sensitive adhesive layer using the peelable base material to the light absorption filter according to the embodiment of the present invention and then aging and curing the composition is used.

The peelable base material is not particularly limited, and a predetermined peelable base material can be used. Examples thereof include the support film in the manufacturing method for the light absorption filter according to the embodiment of the present invention described above.

In addition, the conditions of application, drying, aging, and curing can be appropriately adjusted based on a conventional method.

### [Inorganic Electroluminescent Display Device]

The inorganic electroluminescent display device according to the embodiment of the present invention (hereinafter, also referred to as an “inorganic EL display device”) includes the optical filter according to the embodiment of the present invention.

As another configuration of the inorganic EL display device according to the embodiment of the present invention, a configuration of a generally used inorganic EL display device can be used without particular limitation as long as the optical filter according to the embodiment of the present invention is included. For example, the descriptions regarding the inorganic EL element and the inorganic electroluminescent display device, which are described in JP2005-338640A can be preferably applied.

### [Liquid Crystal Display Device]

The liquid crystal display device according to the embodiment of the present invention includes the optical filter according to the embodiment of the present invention.

The optical filter according to the embodiment of the present invention may be used as at least one of a polarizing plate-protective film or a pressure-sensitive adhesive layer as described later, or it may be included in a backlight unit that is used in the liquid crystal display device.

It is preferable that the liquid crystal display device includes the optical filter according to the embodiment of the present invention, a polarizing plate including a polarizer and a polarizing plate-protective film, a pressure-sensitive adhesive layer, and a liquid crystal cell, where it is preferable that the polarizing plate is bonded to the liquid crystal cell with a pressure-sensitive adhesive layer being interposed. In the liquid crystal display device, the optical filter according to the embodiment of the present invention may also serve as the polarizing plate-protective film or the pressure-sensitive adhesive layer. That is, the liquid crystal display device is divided into a case where the liquid crystal display device includes a polarizing plate including a polarizer and the optical filter (polarizing plate-protective film) according to the embodiment of the present invention, a pressure-sensitive adhesive layer, and a liquid crystal cell, and a case where the liquid crystal display device includes a polarizing plate including a polarizer and a polarizing plate-protective film, the optical filter (pressure-sensitive adhesive layer) according to the embodiment of the present invention, and a liquid crystal cell.

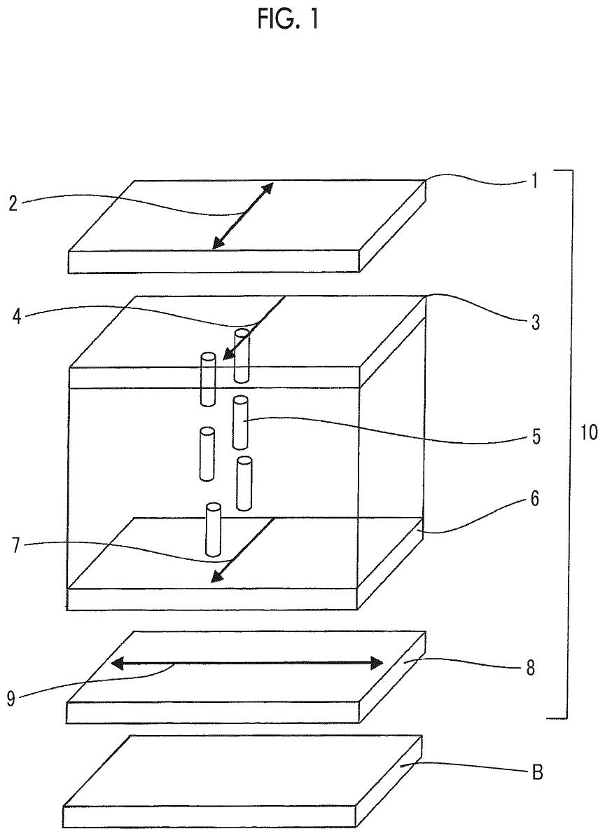

FIG. 1 is a schematic view illustrating an example of the liquid crystal display device according to the embodiment of the present invention. In FIG. 1, a liquid crystal display device 10 consists of a liquid crystal cell having a liquid crystal layer 5 and having a liquid crystal cell upper electrode substrate 3 and a liquid crystal cell lower electrode substrate 6, which are respectively disposed above and below the liquid crystal layer 5, and an upper polarizing plate 1 and a lower polarizing plate 8, which are respectively disposed on both sides of the liquid crystal cell. A color filter layer may be laminated on the upper electrode substrate 3 or the lower electrode substrate 6. On the rear surface of the liquid crystal display device 10, a backlight is disposed. As a light source of the backlight, those described in the above backlight unit can be used.

Each of the upper polarizing plate 1 and the lower polarizing plate 8 has a configuration in which each of them is laminated such that a polarizer is sandwiched between two polarizing plate protective films, and in the liquid crystal display device 10, at least one polarizing plate is preferably a polarizing plate including the optical filter according to the embodiment of the present invention.

In addition, in the liquid crystal display device 10, the liquid crystal cell may be bonded to the polarizing plates (the upper polarizing plate 1 and/or the lower polarizing plate 8) with a pressure-sensitive adhesive layer (not illustrated in the drawing) being interposed. In this case, the optical filter according to the embodiment of the present invention may also serve as the above-described pressure-sensitive adhesive layer.

The liquid crystal display device 10 includes an image direct vision-type liquid crystal display, an image projection-type liquid crystal display device, and a light modulation-type liquid crystal display device. The present invention is effective for an active matrix liquid crystal display device that uses a three-terminal or two-terminal semiconductor element such as a thin film transistor (TFT) or a metal insulator metal (MIM). Of course, it is also effective for a passive matrix liquid crystal display device represented by a super twisted nematic (STN) mode which is called as the time division driving.

In a case where the optical filter according to the embodiment of the present invention is included in the backlight unit, the polarizing plate of the liquid crystal display device may be a general polarizing plate (a polarizing plate that does not include the optical filter according to the embodiment of the present invention) or may be a polarizing plate that includes the optical filter according to the embodiment of the present invention. In addition, the pressure-sensitive adhesive layer may be a typical pressure-sensitive adhesive layer (not the optical filter according to the embodiment of the present invention) or may be a pressure-sensitive adhesive layer formed of the optical filter according to the embodiment of the present invention.

The in plane switching (IPS) mode liquid crystal display device described in paragraphs 0128 to 0136 of JP2010-102296A is preferable as the liquid crystal display device according to the embodiment of the present invention except that the optical filter according to the embodiment of the present invention is used.

### <Polarizing Plate>

The polarizing plate that is used in the present invention includes a polarizer and at least one polarizing plate-protective film.

The polarizing plate that is used in the present invention is preferably a polarizing plate having a polarizer and polarizing plate-protective films on both surfaces of the polarizer, and it is preferable that at least one surface of the polarizer includes the optical filter according to the embodiment of the present invention as the polarizing plate-protective film. The surface of the polarizer opposite to the surface having the optical filter according to the embodiment of the present invention (the polarizing plate-protective film according to the embodiment of the present invention) may have a general polarizing plate-protective film.

The film thickness of the polarizing plate-protective film is preferably 5 μm or more and 120 μm or less, and more preferably 10 μm or more and 100 μm or less. A thinner film is preferable since in a case of being incorporated in the liquid crystal display device, the display unevenness after elapse of time in high temperature and high humidity is less likely to occur. On the other hand, a thicker film is preferable from the viewpoint of stable transportation during film manufacturing and polarizing plate production. In a case where the optical filter according to the embodiment of the present invention also serves as the polarizing plate-protective film, it is preferable that the thickness of the optical filter satisfies the above-described range.

For the polarizing plate that is used in the present invention, the descriptions related to the performance, the shape, the configuration, the polarizer, the method of laminating the polarizer and the polarizing plate-protective film, the functionalization of the polarizing plate, and the like regarding the polarizing plate described in [0299] to [0309] of WO2021/132674A can be applied as they are.

### <Pressure-Sensitive Adhesive Layer>

In the liquid crystal display device according to the embodiment of the present invention, the polarizing plate is preferably bonded to the liquid crystal cell with a pressure-sensitive adhesive layer being interposed. The optical filter according to the embodiment of the present invention may also serve as the pressure-sensitive adhesive layer. In a case where the optical filter according to the embodiment of the present invention does not serve as the pressure-sensitive adhesive layer, a typical pressure-sensitive adhesive layer can be used as the pressure-sensitive adhesive layer.

The pressure-sensitive adhesive layer is not particularly limited as long as the polarizing plate can be bonded to the liquid crystal cell, and for example, an acrylic type, a urethane type, polyisobutylene, or the like is preferable.

In a case where the optical filter according to the embodiment of the present invention also serves as a pressure sensitive adhesive layer, the pressure sensitive adhesive layer includes the coloring agent and the binder resin, and further contains a crosslinking agent, a coupling agent, or the like to impart adhesiveness.

In a case where the optical filter according to the embodiment of the present invention also serves as a pressure-sensitive adhesive layer, the above-described binder resin to be contained in the pressure-sensitive adhesive layer is preferably 90% by mass or more and less than 100% by mass, and more preferably 95% by mass or more and less than 100% by mass.

The content of the coloring agent is as described above.

The thickness of the pressure-sensitive adhesive layer is not particularly limited; however, it is preferably 1 to 50 μm and more preferably 3 to 30 μm.

### <Liquid Crystal Cell>

The liquid crystal cell is not particularly limited, and a typical liquid crystal cell can be used.

### <Ultraviolet Absorbing Layer>

The organic electroluminescent display device, inorganic electroluminescent display device, or liquid crystal display device including the optical filter according to the embodiment of the present invention preferably has a layer (hereinafter, also referred to as an “ultraviolet absorbing layer”) that inhibits the light absorption (the ultraviolet absorption) of the compound B that generates a radical upon ultraviolet irradiation, on the viewer side with respect to the optical filter according to the embodiment of the present invention. In a case where the ultraviolet absorbing layer is provided, it is possible to prevent the fading of the optical filter according to the embodiment of the present invention due to external light.

The ultraviolet absorbing layer will be described below.

### (Ultraviolet Absorbing Agent)

The ultraviolet absorbing layer usually contains a resin and an ultraviolet absorbing agent. From the viewpoint of the excellent absorption capacity of an ultraviolet ray having a wavelength of 370 nm or less and good liquid crystal display properties, an ultraviolet absorbing agent having a small absorption of visible light having a wavelength of 400 nm or more is preferably used.

Specific examples of the ultraviolet absorbing agent preferably used in the present invention include a hindered phenol-based compound, a benzophenone-based compound such as a hydroxybenzophenone-based compound, a benzotriazole-based compound, a salicylic acid ester-based compound, a cyanoacrylate-based compound, and a nickel complex salt-based compound.

Examples of the hindered phenol-based compound include 2,6-di-tert-butyl-p-cresol, pentaerythrityl-tetrakis[3-(3,5-di-tert-butyl-4-hydroxyphenyl)propionate], N,N′-hexamethylene bis(3,5-di-tert-butyl-4-hydroxy-hydrocinnamide), 1,3,5-trimethyl-2,4,6-tris(3,5-di-tert-butyl-4-hydroxybenzyl)benzene, and tris-(3,5-di-tert-butyl-4-hydroxybenzyl)-isocyanurate.

Examples of the benzotriazole-based compound include 2-(2′-hydroxy-5′-methylphenyl) benzotriazole, 2,2-methylene bis(4-(1,1,3,3-tetramethylbutyl)-6-(2H-benzotriazole-2-yl) phenol), 2,4-bis(n-octylthio)-6-(4-hydroxy-3,5-di-tert-butylanilino)-1,3,5-triazine, triethyleneglycol-bis[3-(3-tert-butyl-5-methyl-4-hydroxyphenyl)propionate], N,N′-hexamethylene bis(3,5-di-tert-butyl-4-hydroxy-hydrocinnamide), 1,3,5-trimethyl-2,4,6-tris(3,5-di-tert-butyl-4-hydroxybenzyl)benzene, 2-(2′-hydroxy-3′, 5′-Di-tert-butylphenyl)-5-chlorbenzotriazole, (2-(2′-hydroxy-3′,5′-di-tert-amylphenyl)-5-chlorbenzotriazole, 2,6-di-tert-butyl-p-cresol, and pentaerythrityl-tetrakis[3-(3,5-di-tert-butyl-4-hydroxyphenyl)propionate].

The adding amount of this ultraviolet absorbing agent is preferably 0.1 part by mass to 30.0 parts by mass with respect to 100 parts by mass of the resin.

### (Resin)

As the resin that is used for the ultraviolet absorbing layer, a commonly used compound resin can be used, which is not particularly limited as long as it does not contradict the gist of the present invention. Examples of the resin include a cellulose acylate resin, an acrylic resin, a cycloolefin-based resin, a polyester-based resin, and an epoxy resin.

### (Installation Position of Ultraviolet Absorbing Layer)

The disposition of the ultraviolet absorbing layer is not particularly limited as long as it is on the viewer side with respect to the optical filter according to the embodiment of the present invention, and the ultraviolet absorbing layer can be installed at any position. For example, it is also possible to add an ultraviolet absorbing agent to a member such as a protective film of the polarizing plate, an antireflection film, or the like to impart it a function of an ultraviolet absorbing layer. In addition, an ultraviolet absorbing agent can also be added to the above-described pressure-sensitive adhesive layer.

### EXAMPLES

Hereinafter, the present invention will be described in more detail based on Examples. The materials, using amount, ratio, details of treatment, procedures of treatment, and the like described in Examples below can be appropriately changed without departing from the spirit of the present invention. Therefore, it is to be understood that the scope of the present invention is not limited to Examples described below.

It is noted that “parts” and “%” that indicate the composition in Examples below are based on mass unless otherwise specified. Room temperature means “25° C.”.

It is noted that all steps from a step of preparing a wavelength selective absorption layer forming liquid to a step of producing a base material-attached light absorption filter and a step of carrying out an ultraviolet irradiation test using the base material-attached light absorption filter were carried out under a yellow lamp so that the ultraviolet irradiation was not allowed.

### [Production of Light Absorption Filter]

Materials used to produce the light absorption filter are shown below.

### <Matrix Polymer (Resin)>

### (Resin 1)

A benzyl methacrylate-methacrylic acid random copolymer (manufactured by Fujikura Kasei Co., Ltd., ACRYBASE FF-187 (product name)), methacrylic acid content: 30% by mole, weight-average molecular weight: 27,500.

### (Resin 2)

Polybenzyl methacrylate (manufactured by Sigma-Aldrich Co., LLC, poly(benzyl methacrylate))

It is noted that the methacrylic acid moiety of the resin 1 corresponds to the compound A having an acid group defined in the present invention.

### <Compound B>

4-Phenylquinoline (manufactured by FUJIFILM Wako Pure Chemical Corporation, pKaH: 4.3)

### <Squarine-Based Coloring Agent Represented by General Formula (1)>

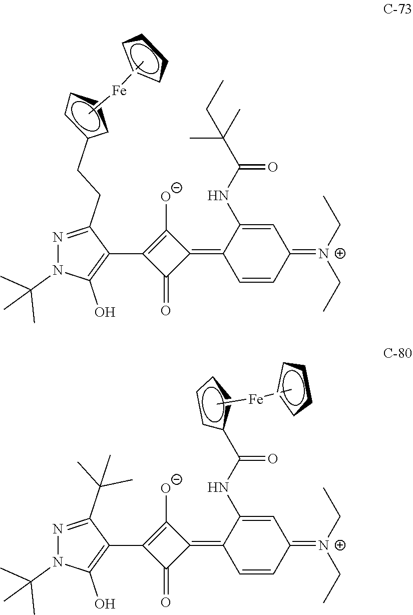

### (Leveling Agent 1)

A polymer surfactant composed of the following constitutional components was used as a leveling agent 1. In the following structural formulae, the proportion of each constitutional component is in terms of a molar ratio, and t-Bu means a tert-butyl group.

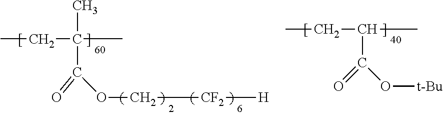

### (Base Material 1)

A polyethylene terephthalate film (manufactured by TORAY INDUSTRIES, Inc., Lumirror XD-510P (product name, film thickness: 50 μm)

### Example 1

<1-1. Production of Wavelength Selective Absorption Layer No. P101>

### (1) Preparation of Resin Solution (Wavelength Selective Absorption Layer Forming Liquid)

The respective components were mixed according to the composition shown below to prepare a wavelength selective absorption layer forming liquid (composition) Ba-1.

Composition of wavelength selective
absorption layer forming liquid Ba-1

| | | |
|---|---|---|
| Resin 1 | 98.4 | parts by mass |
| Leveling agent 1 | 0.08 | parts by mass |
| Coloring agent C-73 | 1.57 | parts by mass |
| Methyl ethyl ketone (solvent) | 566.7 | parts by mass |

Subsequently, the obtained light wavelength selective absorption layer forming liquid Ba-1 was filtered using a filter paper (#63, manufactured by Toyo Roshi Kaisha, Ltd.) having an absolute filtration precision of 10 μm, and further subjected to filtration using a metal sintered filter (product name: Pall filter PMF, media code: FH025, manufactured by Pall) with an absolute filtration precision of 2.5 μm.

### (2) Production of Wavelength Selective Absorption Layer

The wavelength selective absorption layer forming liquid Ba-1 after the filtration treatment was applied onto the base material 1 by using a bar coater so that the film thickness after drying was 2.2 μm, and dried at 120° C. to produce a wavelength selective absorption layer No. P101.

<1-2. Production of Wavelength Selective Absorption Layers Nos. P102 to P106, c21 to c23, r11, and r12>

Wavelength selective absorption layers Nos. P102 to P106, c21 to c23, r11, and r12 were produced in the same manner as in the production of the wavelength selective absorption layer No. P101, except that at least one of the kind of the resin, the kind of the compound B, the kind of the coloring agent, or the blending amount thereof was changed to the content shown in Table 1. It is noted that the description is made such that the wavelength selective absorption layers of the light absorption filters Nos. P102 to P106, c21 to c23, r11, and r12 correspond to the wavelength selective absorption layers Nos. P102 to P106, c21 to c23, r11, and r12, respectively.

### <1-3. Production of Light Absorption Filter Having Gas Barrier Layer and Wavelength Selective Absorption Layer>

For the wavelength selective absorption layer No. P101, a light absorption filter which is obtained by further laminating a gas barrier layer on the wavelength selective absorption layer (hereinafter, simply referred to as a “light absorption filter”) was produced as follows.

### (1) Production of Base Material 3

The wavelength selective absorption layer side of the base material-attached wavelength selective absorption layer which had been produced as described above was subjected to a corona treatment using a corona treatment device (product name: Corona-Plus, manufactured by VETAPHONE), at a discharge amount of 1,000 W·min/m², and at a processing speed of 3.2 μm/min and then used as a base material 3.

### (2) Preparation of Resin Solution

The respective components were according to the composition shown below, and the resultant mixture was stirred in a constant-temperature tank at 90° C. for 1 hour to dissolve Kuraray Exceval AQ-4105 (product name, manufactured by KURARAY Co., Ltd., modified polyvinyl alcohol, saponification degree: 98% to 99% by mole), whereby a gas barrier layer forming liquid was prepared.

Composition of gas barrier layer forming liquid

| Kuraray Exceval AQ-4105 (product name, | 4.0 | parts by mass |
|---|---|---|
| manufactured by KURARAY Co., Ltd.) | | |
| 30% aqueous solution of polyethyl- | 0.33 parts by mass | |
| eneimine (manufactured by | (substantive blending | |
| FUJIFILM Wako Pure | amount polyethyleneimine: | |
| Chemical Corporation) | 0.099 parts by mass | |
| Pure water | 88.2 | parts by mass |
| Isopropyl alcohol | 7.5 | parts by mass |

Subsequently, the obtained gas barrier layer forming liquid was filtered using a filter having an absolute filtration precision of 5 μm (product name: Hydrophobic Fluorepore Membrane, manufactured by Millex).

### (3) Lamination of Gas Barrier Layer

The gas barrier layer forming liquid after the filtration treatment was applied onto the corona-treated surface side of the base material 3 using a bar coater so that the film thickness after drying was 1.6 μm, and dried at 120° C. for 60 seconds to produce a light absorption filter No. P101.

This light absorption filter No. P101 has a configuration in which a base material 1, a wavelength selective absorption layer, and a gas barrier layer (an adjacent layer) are laminated in this order.

<1-4. Production of Light Absorption Filters Nos. P102 to P106, c21 to c23, r11, and r12>

Light absorption filters Nos. P102 to P106, c21 to c23, r11, and r12 were produced in the same manner as in the production of the light absorption filter No. P101, except that the blending amount of polyethyleneimine was changed to the content shown in Table 1.

Here, Nos. P101 to P106 are the light absorption filters according to the embodiment of the present invention, Nos. c21 to c23 are light absorption filters for comparison, and Nos. r11 and r12 are light absorption filters for reference.

### <Absorbance of Light Absorption Filter (Before Ultraviolet Irradiation)>

### (1) Measurement of Absorbance

Using a UV3600 spectrophotometer (product name) manufactured by Shimadzu Corporation, the absorbance of the light absorption filter and the standard filter in a wavelength range of 380 to 800 nm was measured for every 1 nm. It is noted that the optical path length is 2.2 μm.

The standard filter for the light absorption filters Nos. P101 to P105, c21, and c22 is the light absorption filter No. r11 that does not contain the coloring agent, the compound B, and the basic compound.

The standard filter for the light absorption filters Nos. P106 and c23 is the light absorption filter No. r12 that does not contain the coloring agent, the compound B, and the basic compound.

### (2) Calculation of Absorbance

Using the absorbance value Abₓ (λ) of the light absorption filter at each wavelength λ nm measured as described above and the absorbance value Ab₀ (λ) of the standard filter containing the same resin at each wavelength λ nm, the absorbance Ab (λ) of the light absorption filter before ultraviolet irradiation was calculated according to the following expression.

$$Ab ( λ ) = {Ab}_{x} ( λ ) - {Ab}_{0} ( λ )$$

Hereinafter, among the absorbances Ab (λ) of the light absorption filter in a wavelength range of 400 to 700 nm, the wavelength at which the highest absorbance Ab (λ) among the wavelengths at which the highest maximal absorption is exhibited was defined as the maximal absorption wavelength (hereinafter, also simply referred to as “λₘₐₓ”), and the absorbance at λₘₐₓ was defined as the absorption maximal value (hereinafter, also simply referred to as “Ab (λₘₐₓ)”)

### <<Evaluation>>

The light resistance and the heat resistance of each light absorption filter were evaluated. In addition, the decolorization rate was also calculated for a part of the light absorption filters.

The results are summarized in Table 1 below.

### (Ultraviolet Irradiation Test)

Using an ultra-high pressure mercury lamp (manufactured by HOYA Corporation, product name: UL750) under atmospheric pressure (101.33 kPa), the light absorption filter and the standard filter were irradiated at room temperature with an ultraviolet ray at an illuminance of 100 mW/cm² and an irradiation amount of 1,000 mJ/cm² from the gas barrier layer (the side opposite to the base material 1).

<Absorbance of Light Absorption Filter (after Ultraviolet Irradiation)>

Using the light absorption filter after ultraviolet irradiation and the standard filter, the absorbance Ab (λ) after ultraviolet irradiation was calculated according to the same method as described in <Absorbance of light absorption filter (before ultraviolet irradiation)> described above.

### [1-1. Light Resistance]

### (Production of Light Resistance Evaluation Film)

A triacetyl cellulose film (product name: Fujitac TG60UL, manufactured by FUJIFILM Corporation) having a thickness of 60 μm was bonded to the side of the gas barrier layer (adjacent layer) of the light absorption filter with a pressure sensitive adhesive 1 (product name: SK2057, manufactured by Soken Chemical & Engineering Co., Ltd.) having a thickness of about 20 μm being interposed. Subsequently, glass was bonded to the substrate 1 side with the pressure sensitive adhesive 1 being interposed, whereby a light resistance evaluation film was produced.

The obtained light resistance evaluation film has a configuration in which the lamination is carried out in the following order; glass, a layer of the pressure-sensitive adhesive 1, the base material 1, the wavelength selective absorption layer, the gas barrier layer, a layer of the pressure-sensitive adhesive agent 1, and the triacetyl cellulose film.

### (Absorption Maximal Value of Light Resistance Evaluation Film)

Using a UV3600 spectrophotometer (product name) manufactured by Shimadzu Corporation, the absorbance of the light resistance evaluation film in a wavelength range of 200 to 1,000 nm was measured for every 1 nm. An absorbance difference between the absorbance of the light resistance evaluation film at each wavelength and the absorbance of the light resistance evaluation film having the same configuration except that it did not contain the coloring agent, the compound B, and the basic compound was calculated, and the maximum value of this absorbance difference was defined as the absorption maximal value.

That is, in the light resistance evaluation film of the light absorption filters Nos. P101 to P105 and c21 and c22, the absorbance difference was calculated by using the light resistance evaluation film of the light absorption filter No. r11, which does not contain the coloring agent, the compound B, and the basic compound. In addition, in the light resistance evaluation film of the light absorption filters Nos. P106 and c23, the absorbance difference was calculated by using the light resistance evaluation film of the light absorption filter No. r12, which does not contain the coloring agent, the compound B, and the basic compound.

### (Light Resistance)

The light resistance evaluation film was irradiated with light for 200 hours in an environment of 60° C. and 50% relative humidity with Super Xenon Weather Meter SX75 (product name) manufactured by Suga Test Instruments Co., Ltd., and each of the absorption maximal values before and after this irradiation was measured, and the light resistance was calculated according to the following expression.

$$[ Light resistance ( \% ) ] = ( [ absorption maximal value after light irradiation for 200 hours ] \text{} / [ absorption maximal value before light irradiation ] ) \times 100$$

### [1-2. Heat Resistance]

An evaluation film was prepared by the same method as in the content described in the section of the light resistance test, the present evaluation film was stored for 500 hours in an environment of 80° C. and a humidity of 10% or less, and each absorption maximal value before and after the storage was measured, to calculate the heat resistance according to the following expression.

$$[ Heat resistance ( \% ) ] = [ ( absorption maximal value after storage for 500 hours ] / [ absorption maximal value at initial stage ( before storage for 500 hours ) ] ) \times 100$$

### [1-3. Decolorization Rate]

The decolorization rate was calculated according to the following expression using the absorption maximal values (Ab (λₘₐₓ)) before and after the ultraviolet irradiation test.

$$Decolorization rate ( \% ) = 100 - ( Ab ( {λ}_{max} ) after ultraviolet irradiation / Ab ( {λ}_{max} ) before ultraviolet irradiation ) \times 100 \%$$

[1-4. Absorption (Secondary Absorption) Derived from New Coloration Structure, Associated with Decomposition of Coloring Agent]

It is noted that in the light absorption filters Nos. P104, P105, and c22, a value obtained by subtracting the ratio of (I) from the ratio of (II), which are defined in the above-described paragraph [0164], was 2% or less, and the secondary absorption associated with the decomposition of the coloring agent upon ultraviolet irradiation was suppressed.

TABLE 1

| | | | | | | | | Evaluation | | |
|---|---|---|---|---|---|---|---|---|---|---|
| | | | | | | | | | | Decolor- |
| | | | | | | | | | | ization |
| | | | | | | | | | | property |
| | Wavelength selective absorption layer | | | | | | | | | due to |
| | | Squarine-based | | | | | | | | ultraviolet |
| | | coloring agent | | | | | | Light | Heat | irradiation |
| | | represented by | | | | | | resistance | resistance | Decolor- |
| | | General | | | | Gas barrier layer | | Residual | Residual | ization |
| Light | Resin | Formula (1) | | Compound B | | Basic compound | | rate | rate | rate |
| absorption | (compound A) | | Blending | | Blending | | Blending | [xenon | [80° C., | [1,000 |
| filter No. | Kind | Kind | amount | Kind | amount | Kind | amount | 200 hr] | 500 hr] | mJ/cm²] |
| P101 | Resin 1 | C-73 | 1.57 | Absent | 0 | Polyethyleneimine | 2.5 | 75% | 81% | 5% or less |
| P102 | Resin 1 | C-73 | 1.57 | Absent | 0 | Polyethyleneimine | 5 | 81% | 84% | 5% or less |
| P103 | Resin 1 | C-73 | 1.57 | Absent | 0 | Polyethyleneimine | 10 | 80% | 82% | 5% or less |
| P104 | Resin 1 | C-80 | 1.47 | 4- | 12.6 | Polyethyleneimine | 2.5 | 85% | 95% | 90% |
| | | | | phenylquinoline | | | | | | |
| P105 | Resin 1 | C-80 | 1.47 | 4- | 12.6 | Polyethyleneimine | 5 | 88% | 92% | 92% |
| | | | | phenylquinoline | | | | | | |
| P106 | Resin 2 | C-73 | 1.57 | Absent | 0 | Polyethyleneimine | 2.5 | 94% | 84% | 5% or less |
| r11 | Resin 1 | Absent | Absent | Absent | Absent | Absent | Absent | — | — | — |
| c21 | Resin 1 | C-73 | 1.57 | Absent | 0 | Absent | Absent | 69% | 63% | 5% or less |
| c22 | Resin 1 | C-80 | 1.47 | 4- | 12.6 | Absent | Absent | 75% | 92% | 86% |
| | | | | phenylquinoline | | | | | | |
| r12 | Resin 2 | Absent | Absent | Absent | Absent | Absent | Absent | — | — | — |
| c23 | Resin 2 | C-73 | 1.57 | Absent | 0 | Absent | Absent | 82% | 83% | 5% or less |

### (Note in Table)

The blending amount of the coloring agent and the compound B means a blending amount in terms of parts by mass with respect to 100 parts by mass of the wavelength selective absorption layer.

The blending amount of the basic compound means a blending amount in terms of parts by mass with respect to 100 parts by mass of the gas barrier layer excluding the basic compound.

Regarding the standard filter not containing the coloring agent, the column of the evaluation is indicated by “-”.

From the results in Table 1, it can be seen that the light absorption filters Nos. P101 to P103 according to the embodiment of the present invention, which contains polyethyleneimine as a basic compound in the gas barrier layer which is an adjacent layer, have both excellent light resistance and excellent heat resistance as compared with the comparative light absorption filter No. c21 containing no polyethyleneimine.

Similarly, as compared with the comparative light absorption filter No. c22 containing no polyethyleneimine, the light absorption filters Nos. P104 and P105 according to the embodiment of the present invention had excellent light resistance and also had excellent heat resistance as high as or higher than the heat resistance of the comparative light absorption filter No. c22. The light absorption filter No. P106 according to the embodiment of the present invention had both excellent light resistance and excellent heat resistance as compared with the comparative light absorption filter No. c23 containing no polyethyleneimine.

In addition, from the comparison between Nos. P104 and P105 which are the light absorption filters having the decolorization property and No. c22, it can be seen that the light absorption filters Nos. P104 and P105 according to the embodiment of the present invention have excellent light resistance and excellent heat resistance as compared with the comparative light absorption filter No. c22, and further have an excellent decolorization rate as well.

Reference Example: An embodiment in which the wavelength selective absorption layer contains a compound A that has an acid group and a compound B that forms a hydrogen bond with the acid group contained in the compound A and generates a radical upon ultraviolet irradiation

### [Production of Light Absorption Filter]

In the reference example, Materials used to produce the light absorption filter are shown below.

### <Matrix Polymer (Resin)>

### (Resin 1)

A benzyl methacrylate-methacrylic acid random copolymer (manufactured by Fujikura Kasei Co., Ltd., ACRYBASE FF-187 (product name)), methacrylic acid content: 30% by mole, weight-average molecular weight: 27,500.

### (Resin 2)

A cyclohexyl methacrylate-methacrylic acid random copolymer, methacrylic acid content: 29% by mole, weight-average molecular weight: 26,300.

### (Resin 3)

An isobornyl methacrylate-methacrylic acid random copolymer, methacrylic acid content: 35% by mole, weight-average molecular weight: 27,200.

### (Resin 4)

Polybenzyl methacrylate (manufactured by Sigma-Aldrich Co., LLC, poly(benzyl methacrylate))

### (Resin 5)

A cyclic polyolefin resin (APL6509T (product name), manufactured by Mitsui Chemicals, Inc., a copolymer of ethylene and norbornene, glass transition temperature Tg: 80° C.)

It is noted that the methacrylic acid moiety of the resins 1 to 3 corresponds to the compound A having an acid group defined in the present invention.

### <Compound B>

Quinoline (manufactured by Tokyo Chemical Industry Co., Ltd.)
2-methylquinoline (manufactured by Sigma-Aldrich Co. LLC, Quinaldine)
4-methylquinoline (manufactured by Sigma-Aldrich Co. LLC., Lepidine)
2,4-dimethylquinoline (manufactured by Tokyo Chemical Industry Co., Ltd.)
Isoquinoline (manufactured by Tokyo Chemical Industry Co., Ltd.)
3-methylisoquinoline (manufactured by Sigma-Aldrich Co. LLC.)

### <Photoradical Generator>

4,4′-dimethoxybenzophenone

### <Squarine-Based Coloring Agent (Dye) Represented by General Formula (1)>

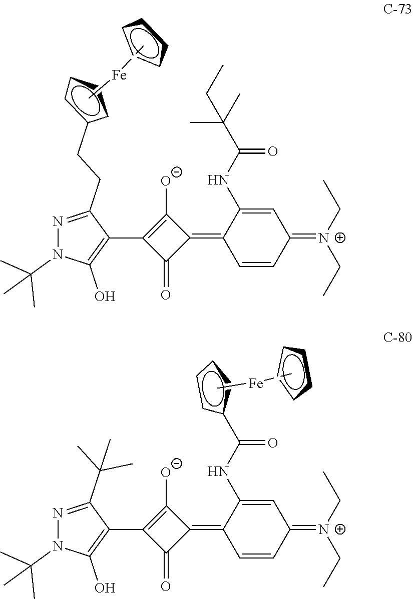

### (Leveling Agent 1)

A polymer surfactant composed of the following constitutional components was used as a leveling agent 1. In the following structural formulae, the proportion of each constitutional component is in terms of a molar ratio, and t-Bu means a tert-butyl group.

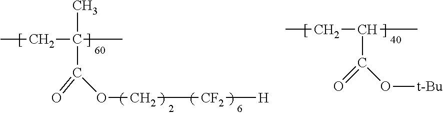

### (Base Material 1)

A polyethylene terephthalate film (manufactured by TORAY INDUSTRIES, Inc., Lumirror XD-510P (product name, film thickness: 50 μm)

### (Base Material 2)

A cellulose acylate film (manufactured by FUJIFILM Corporation, product name: ZRD40SL)

### <2-1. Production of Wavelength Selective Absorption Layer No. 101>

### (1) Preparation of Resin Solution (Wavelength Selective Absorption Layer Forming Liquid)

The respective components were mixed according to the composition shown below to prepare a wavelength selective absorption layer forming liquid (composition) Ba-1.

Composition of wavelength selective
absorption layer forming liquid Ba-1

| | | |
|---|---|---|
| Resin 1 | 82.8 | parts by mass |
| Leveling agent 1 | 0.08 | parts by mass |
| Coloring agent C-73 | 1.57 | parts by mass |
| Quinoline (manufactured by Tokyo Chemical | 15.5 | parts by mass |
| Industry Co., Ltd.) | | |
| Methyl ethyl ketone (solvent) | 566.7 | parts by mass |

Subsequently, the obtained light wavelength selective absorption layer forming liquid Ba-1 was filtered using a filter paper (#63, manufactured by Toyo Roshi Kaisha, Ltd.) having an absolute filtration precision of 10 μm, and further subjected to filtration using a metal sintered filter (product name: Pall filter PMF, media code: FH025, manufactured by Pall) with an absolute filtration precision of 2.5 μm.

### (2) Production of Wavelength Selective Absorption Layer

The wavelength selective absorption layer forming liquid Ba-1 after the filtration treatment was applied onto the base material 1 by using a bar coater so that the film thickness after drying was 2.5 μm, and dried at 120° C. to produce a wavelength selective absorption layer No. 101.

<2-2. Production of Wavelength Selective Absorption Layers Nos. 102 to 121, r201 to r204, c205, and c206>

Wavelength selective absorption layers Nos. 102 to 121, r201 to r204, c205, and c206 were produced in the same manner as in the production of the wavelength selective absorption layer No. 101, except that at least one of the kind of the matrix polymer (resin), the kind of the compound B, the kind of the coloring agent, or the blending amount thereof was changed to the content described in Table 2.

Here, Nos. 101 to 121 are wavelength selective absorption layers containing the compound A and the compound B which are defined in the present invention, Nos. c205 and c206 are wavelength selective absorption layers for comparison, and Nos. r201 to r204 are wavelength selective absorption layers for reference.

<2-3. Production of Wavelength Selective Absorption Layer No. c207>

### (1) Preparation of Resin Solution (Wavelength Selective Absorption Layer Forming Liquid)

The respective components were mixed according to the composition shown below to prepare a wavelength selective absorption layer forming liquid (composition) Ba-2.

Composition of wavelength selective
absorption layer forming liquid Ba-2

| | | |
|---|---|---|
| Resin 5 | 93.5 | parts by mass |
| Coloring agent C-73 | 1.57 | parts by mass |
| Photoradical generator: 4,4′- | 1.37 | parts by mass |
| dimethoxybenzophenone (manufactured | | |
| by Tokyo Chemical Industry Co., Ltd.) | | |
| Peelability control resin component: | 3.4 | parts by mass |
| TUFTEC H-1043 (product name, | | |
| manufactured by Asahi Kasei | | |
| Corporation) | | |
| Leveling agent: MEGAFACE F-554 | 0.16 | parts by mass |
| (product name, manufactured by | | |
| DIC Corporation) Mar) | | |
| Cyclohexane (solvent) | 770.0 | parts by mass |

Subsequently, the obtained light wavelength selective absorption layer forming liquid Ba-2 was filtered using a filter paper (#63, manufactured by Toyo Roshi Kaisha, Ltd.) having an absolute filtration precision of 10 μm, and further subjected to filtration using a metal sintered filter (product name: Pall filter PMF, media code: FH025, manufactured by Pall) with an absolute filtration precision of 2.5 μm.

### (2) Production of Wavelength Selective Absorption Layer

The wavelength selective absorption layer forming liquid Ba-2 after the filtration treatment was applied onto the base material 2 by using a bar coater so that the film thickness after drying was 2.5 μm, and dried at 120° C. to produce a wavelength selective absorption layer No. c207.

<2-4. Production of Wavelength Selective Absorption Layer No. r208>

A wavelength selective absorption layer No. r208 was produced in the same manner as in the production of the wavelength selective absorption layer No. c207, except that the coloring agent and the photoradical generator were changed to the content described in Table 2 so that the dye and the photoradical generator were not blended.

Here, No. c207 is a wavelength selective absorption layer for comparison, and No. r208 is a wavelength selective absorption layer for reference.

### <2-5. Production of Light Absorption Filter Having Gas Barrier Layer and Wavelength Selective Absorption Layer>

For the wavelength selective absorption layers Nos. 101 to 121, r201 to r204, c205 to c207, and r208, a light absorption filter which is obtained by further laminating a gas barrier layer on the wavelength selective absorption layer (hereinafter, simply referred to as a “light absorption filter”) was produced as follows.

### (1) Production of Base Material 4

The wavelength selective absorption layer side of the base material-attached wavelength selective absorption layer was subjected to a corona treatment using a corona treatment device (product name: Corona-Plus, manufactured by VETAPHONE), at a discharge amount of 1,000 W·min/m², and at a processing speed of 3.2 μm/min and then used as a base material 4.

### (2) Preparation of Resin Solution

The respective components were according to the composition shown below, and the resultant mixture was stirred in a constant-temperature tank at 90° C. for 1 hour to dissolve Kuraray Exceval AQ-4105 (product name, manufactured by KURARAY Co., Ltd., modified polyvinyl alcohol, saponification degree: 98% to 99% by mole), whereby a gas barrier layer forming liquid was prepared.

Composition of gas barrier layer forming liquid

| | | |
|---|---|---|
| Kuraray Exceval AQ-4105 (product name, | 4.0 | parts by mass |
| manufactured by KURARAY Co., Ltd.) | | |
| Pure water | 88.5 | parts by mass |
| Isopropyl alcohol | 7.5 | parts by mass |

Subsequently, the obtained gas barrier layer forming liquid was filtered using a filter having an absolute filtration precision of 5 μm (product name: Hydrophobic Fluorepore Membrane, manufactured by Millex).

### (3) Lamination of Gas Barrier Layer

The gas barrier layer forming liquid after the filtration treatment was applied onto the corona-treated surface side of the base material 4 using a bar coater so that the film thickness after drying was 1.6 μm, and dried at 120° C. for 60 seconds to produce a light absorption filter.

This light absorption filter has a configuration in which the base material 1 or the base material 2, the wavelength selective absorption layer, and the gas barrier layer are laminated in this order.

### <Absorbance of Light Absorption Filter (Before Ultraviolet Irradiation)>

### (1) Measurement of Absorbance

Using a UV3600 spectrophotometer (product name) manufactured by Shimadzu Corporation, the absorbance of the light absorption filter and the standard filter in a wavelength range of 380 to 800 nm was measured for every 1 nm. It is noted that the optical path length is 2.5 μm.

A standard filter for the light absorption filters Nos. 101 to 107, and c205, which contain the resin 1, is the light absorption filter No. r201 which has been changed not to contain the coloring agent and the compound B.

A standard filter for the light absorption filters Nos. 108 to 114 which contain the resin 2, is the light absorption filter No. r202 which has been changed not to contain the dye and the compound B.

A standard filter for the light absorption filters Nos. 115 to 121 which contain the resin 3, is the light absorption filter No. r203 which has been changed not to contain the coloring agent and the compound B.

A standard filter for the light absorption filter No. c206 which contains the resin 4, is the light absorption filter No. r204 which has been changed not to contain the coloring agent and the compound B.

A standard filter for the light absorption filter No. c207 which contains the resin 5, is the light absorption filter No. r208 which has been changed not to contain the coloring agent and the photoradical generator.

### (2) Calculation of Absorbance

Using the absorbance value Abₓ (λ) of the light absorption filter at each wavelength k nm measured as described above and the absorbance value Ab₀ (λ) of the standard filter containing the same resin at each wavelength λ nm, the absorbance Ab (λ) of the light absorption filter before ultraviolet irradiation was calculated according to the following expression.

$$Ab ( λ ) = {Ab}_{x} ( λ ) - {Ab}_{0} ( λ )$$

Hereinafter, among the absorbances Ab (λ) of the light absorption filter in a wavelength range of 400 to 700 nm, the wavelength at which the highest absorbance Ab (λ) among the wavelengths at which the highest maximal absorption is exhibited was defined as the maximal absorption wavelength (hereinafter, also simply referred to as “λₘₐₓ”), and the absorbance at λₘₐₓ was defined as the absorption maximal value (hereinafter, also simply referred to as “Ab (λₘₐₓ)”).

### <<Evaluation 1>>

The decolorization rate and the heat resistance of each light absorption filter were evaluated.

The results are summarized in Table 3 below.

### (Ultraviolet Irradiation Test)

Using an ultra-high pressure mercury lamp (manufactured by HOYA Corporation, product name: UL750) under atmospheric pressure (101.33 kPa), the light absorption filter and the standard filter were irradiated at room temperature with an ultraviolet ray (UV) at an illuminance of 100 mW/cm² and an irradiation amount of 500 mJ/cm² from the gas barrier layer (the side opposite to the base material 1 or the base material 2).

<Absorbance of Light Absorption Filter (after Ultraviolet Irradiation)>

Using the light absorption filter after ultraviolet irradiation and the standard filter, the absorbance Ab (λ) after ultraviolet irradiation was calculated according to the same method as described in <Absorbance of light absorption filter (before ultraviolet irradiation)> described above.

### [2-1. Evaluation of Decolorization Rate]

The decolorization rate was calculated according to the following expression using the absorption maximal values (Ab (λₘₐₓ)) before and after the ultraviolet irradiation test.

$$Decolorization rate ( \% ) = 100 - ( Ab ( {λ}_{max} ) after ultraviolet irradiation / Ab ( {λ}_{max} ) before ultraviolet irradiation ) \times 100$$

[2-2. Absorption (Secondary Absorption) Derived from New Coloration Structure, Associated with Decomposition of Coloring Agent]

It is noted that in all of the light absorption filters Nos. 101 to 121, a value obtained by subtracting the ratio of (I) from the ratio of (II), which are defined in the above-described paragraph [0164], was 5.0% or less, and the secondary absorption associated with the decomposition of the coloring agent upon ultraviolet irradiation was suppressed.

### [2-3. Evaluation of Heat Resistance]

A triacetyl cellulose film (product name: Fujitac TG60UL, manufactured by FUJIFILM Corporation) having a thickness of 60 μm was bonded to the side of the gas barrier layer of the light absorption filter with a pressure sensitive adhesive 1 (product name: SK2057, manufactured by Soken Chemical & Engineering Co., Ltd.) having a thickness of about 20 μm being interposed. Subsequently, the base material 1 or base material 2 was peeled off, and glass was bonded to the light absorption filter side to which the base material 1 or base material 2 was bonded while interposing the pressure sensitive adhesive 1 to produce a heat resistance evaluation film.

The obtained heat resistance evaluation film has a configuration in which the lamination is carried out in the following order; glass, a layer of the pressure-sensitive adhesive 1, the wavelength selective absorption layer, the gas barrier layer, a layer of the pressure-sensitive adhesive agent 1, and the triacetyl cellulose film.

### (Absorption Maximal Value of Heat Resistance Evaluation Film)

Using a UV3600 spectrophotometer (product name) manufactured by Shimadzu Corporation, the absorbance of the heat resistance evaluation film in a wavelength range of 400 to 1,000 nm was measured for every 1 nm. An absorbance difference between the absorbance of the heat resistance evaluation film at each wavelength and the absorbance of the heat resistance evaluation film having the same configuration except that it does not contain the coloring agent and the compound B was calculated, and the maximum value of this absorbance difference was defined as the absorption maximal value.

It is noted that in heat resistance test sample Nos. 101 to 107 and No. c205, an absorbance difference was calculated using the heat resistance evaluation film of the laminate No. r201 which did not contain the coloring agent and the compound B, in heat resistance test sample Nos. 108 to 114, an absorbance difference was calculated using the heat resistance evaluation film of the laminate No. r202 which did not contain the coloring agent and the compound B, in heat resistance test sample Nos. 115 to 121, an absorbance difference was calculated using the heat resistance evaluation film of the laminate No. r203 which did not contain the coloring agent and the compound B, in a heat resistance test sample No. c206, an absorbance difference was calculated using the heat resistance evaluation film of the laminate No. r204 which did not contain the coloring agent and the compound B, and in a heat resistance test sample No. c207, an absorbance difference was calculated using the heat resistance evaluation film of the laminate No. r208 which did not contain the coloring agent and the photoradical generator.

### (Heat Resistance)

Each heat resistance evaluation film was stored for 24 hours in an environment of 105° C. and a humidity of 10% or less, the respective absorption maximal values before and after this storage were measured, and the heat resistance was calculated according to the following expression.

$$[ Heat resistance ( \% ) ] = ( [ absorption maximal value after storage for 24 hours ] / [ absorption maximal value at initial stage ( before storage for 24 hours ) ] ) \times 100$$

TABLE 2

| | | Dye | | Compound B | | |
|---|---|---|---|---|---|---|
| Light absorption | Resin | | Blending | | Blending | pKaH of |
| filter No. | (compound A) | Kind | amount | Kind | amount | compound B |
| 101 | Resin 1 | C-73 | 1.57 | Quinoline | 15.5 | 4.2 |
| 102 | Resin 1 | C-73 | 1.57 | 2-methylquinoline | 17.2 | 4.8 |
| 103 | Resin 1 | C-73 | 1.57 | 4-methylquinoline | 17.2 | 5.1 |
| 104 | Resin 1 | C-73 | 1.57 | 2,4-dimethylquinoline | 18.9 | 5.7 |
| 105 | Resin 1 | C-73 | 1.57 | Isoquinoline | 15.5 | 4.7 |
| 106 | Resin 1 | C-73 | 1.57 | 3-methylisoquinoline | 17.2 | 5.2 |
| 107 | Resin 1 | C-80 | 1.47 | 4-methylquinoline | 17.2 | 5.1 |
| 108 | Resin 2 | C-73 | 1.57 | Quinoline | 15.5 | 4.2 |
| 109 | Resin 2 | C-73 | 1.57 | 2-methylquinoline | 17.2 | 4.8 |
| 110 | Resin 2 | C-73 | 1.57 | 4-methylquinoline | 17.2 | 5.1 |
| 111 | Resin 2 | C-73 | 1.57 | 2,4-dimethylquinoline | 18.9 | 5.7 |
| 112 | Resin 2 | C-73 | 1.57 | Isoquinoline | 15.5 | 4.7 |
| 113 | Resin 2 | C-73 | 1.57 | 3-methylisoquinoline | 17.2 | 5.2 |
| 114 | Resin 2 | C-80 | 1.47 | 4-methylquinoline | 17.2 | 5.1 |
| 115 | Resin 3 | C-73 | 1.57 | Quinoline | 15.5 | 4.2 |
| 116 | Resin 3 | C-73 | 1.57 | 2-methylquinoline | 17.2 | 4.8 |
| 117 | Resin 3 | C-73 | 1.57 | 4-methylquinoline | 17.2 | 5.1 |
| 118 | Resin 3 | C-73 | 1.57 | 2,4-dimethylquinoline | 18.9 | 5.7 |
| 119 | Resin 3 | C-73 | 1.57 | Isoquinoline | 15.5 | 4.7 |
| 120 | Resin 3 | C-73 | 1.57 | 3-methylisoquinoline | 17.2 | 5.2 |
| 121 | Resin 3 | C-80 | 1.47 | 4-methylquinoline | 17.2 | 5.1 |
| r201 | Resin 1 | Absent | Absent | Absent | Absent | — |
| r202 | Resin 2 | Absent | Absent | Absent | Absent | — |
| r203 | Resin 3 | Absent | Absent | Absent | Absent | — |
| r204 | Resin 4 | Absent | Absent | Absent | Absent | — |
| c205 | Resin 1 | C-73 | 1.57 | Absent | Absent | — |
| c206 | Resin 4 | C-73 | 1.57 | 2,4-dimethylquinoline | 18.9 | 5.7 |
| c207 | Resin 5 | C-73 | 1.57 | 4,4′-dimethoxybenzophenone | 1.37 | — |
| r208 | Resin 5 | Absent | Absent | Absent | Absent | — |

TABLE 3

| | Decolorization rate | Heat resistance |
|---|---|---|
| Light absorption | [irradiation amount: | [storage condition: |
| filter No. | 500 mJ/cm²] | 105° C., 24 hr] |
| 101 | 18% | 80% |
| 102 | 37% | 80% |
| 103 | 60% | 86% |
| 104 | 76% | 65% |
| 105 | 25% | 83% |
| 106 | 46% | 87% |
| 107 | 54% | 94% |
| 108 | 55% | 92% |
| 109 | 66% | 86% |
| 110 | 78% | 83% |
| 111 | 87% | 68% |
| 112 | 65% | 92% |
| 113 | 84% | 92% |
| 114 | 73% | 88% |
| 115 | 60% | 94% |
| 116 | 69% | 90% |
| 117 | 79% | 85% |
| 118 | 78% | 81% |
| 119 | 68% | 94% |
| 120 | 84% | 95% |
| 121 | 74% | 90% |
| c205 | 5% or less | 62% |
| c206 | 5% or less | 60% |
| c207 | 5% or less | 90% |

### (Note in Table)

The blending amount of the coloring agent, the compound B, and the photoradical generator means an amount in terms of parts by mass with respect to 100 parts by mass of the wavelength selective absorption layer.

It is noted that 4,4′-dimethoxybenzophenone that is used in No. c207 is a photoradical generator, and it is described in the column of the compound B for convenience.

Regarding the filter that does not contain the compound B, the column of pKaH of the compound B is indicated by “-”.

From the results in Table 2 and Table 3, the following facts can be seen.

The light absorption filters Nos. 101 to 121 according to the embodiment of the present invention, which contain the compound A and the compound B which are defined in the present invention, are preferable since they are excellent in the decolorization property upon irradiation with ultraviolet rays (UV) as compared with the light absorption filter No. c205 of Comparative Example which does not contain the compound B, the light absorption filters No. c206 of Comparative Example which does not contain the compound A having an acid group, and No. c207 of Comparative Example which contains the compound A having an acid group and a photoradical generator instead of the compound B.

In particular, the light absorption filters Nos. 108 to 121 which are obtained by combining the compound B with the resin 2 and the resin 3 having an alicyclic structure are particularly preferable since they are excellent in both decolorization property upon ultraviolet irradiation and heat resistance.

### Example 2

### <3-1. Production of Wavelength Selective Absorption Layer No. 301>

### (Matrix Polymer (Resin))

Arton RX4500 (product name, manufactured by JSR Corporation, a norbornene-based polymer, Tg: 132° C.), which is a cyclic polyolefin resin, was used as a resin 9.

### (Peelability Control Resin Component 3)

TUFTEC M1943 (product name, manufactured by Asahi Kasei Corporation, hydrogenated styrene-based thermoplastic elastomer (SEBS)) was used as a peelability control resin component 3.

### (Coloring Agent)

The above-described coloring agent (C-73), which is a squarine-based coloring agent represented by General Formula (1), was used as a coloring agent.

### (Base Material 1)

A polyethylene terephthalate film (manufactured by TORAY INDUSTRIES, Inc., Lumirror XD-510P (product name, film thickness: 50 μm)

### (Association Inhibitor)

The following association inhibitor 303 was used as an association inhibitor.

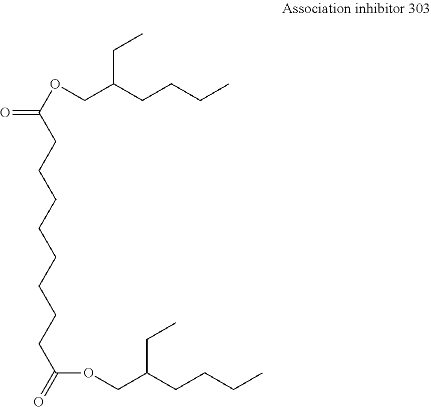 [SMILES: CCCCC(CC)COC(=O)CCCCCCCCC(=O)OCC(CC)CCCC]

### (1) Preparation of Resin Solution (Wavelength Selective Absorption Layer Forming Liquid)

The respective components were mixed according to the composition shown below to prepare a wavelength selective absorption layer forming liquid (composition) Ba-3.

Composition of wavelength selective
absorption layer forming liquid Ba-3

| | | |
|---|---|---|
| Resin 9 | 91.9 | parts by mass |
| Peelability control resin component 3 | 3.4 | parts by mass |
| Leveling agent: MEGAFACE F-554 | 0.08 | parts by mass |
| (manufactured by DIC | | |
| Corporation, fluoropolymer) | | |
| Coloring agent C-73 | 0.88 | parts by mass |
| Association inhibitor 303 | 4.10 | parts by mass |
| Toluene (solvent) | 693.0 | parts by mass |
| Cyclohexanone (solvent) | 77.0 | parts by mass |

Subsequently, the obtained light wavelength selective absorption layer forming liquid Ba-3 was filtered using a filter paper (#63, manufactured by Toyo Roshi Kaisha, Ltd.) having an absolute filtration precision of 10 μm, and further subjected to filtration using a metal sintered filter (product name: Pall filter PMF, media code: FH025, manufactured by Pall) with an absolute filtration precision of 2.5 μm.

### (2) Production of Wavelength Selective Absorption Layer No. 301

The wavelength selective absorption layer forming liquid Ba-3 after the filtration treatment was applied onto the base material 1 by using a bar coater so that the film thickness after drying was 1.2 μm, and dried at 120° C. to produce a wavelength selective absorption layer No. 301.

### <3-2. Production of Light Absorption Filter Having Gas Barrier Layer and Wavelength Selective Absorption Layer>

A light absorption filter which is obtained by further laminating a gas barrier layer on the wavelength selective absorption layer No. 301 (hereinafter, simply referred to as a “light absorption filter”) was produced as follows.

### (1) Production of Base Material 5

The wavelength selective absorption layer side of the base material-attached wavelength selective absorption layer was subjected to a corona treatment using a corona treatment device (product name: Corona-Plus, manufactured by VETAPHONE), at a discharge amount of 1,000 W·min/m², and at a processing speed of 3.2 μm/min and then used as a base material 5.

### (2) Preparation of Resin Solution

The respective components were according to the composition shown below, and the resultant mixture was stirred in a constant-temperature tank at 90° C. for 1 hour to dissolve Kuraray Exceval AQ-4105 (product name, manufactured by KURARAY Co., Ltd., modified polyvinyl alcohol, saponification degree: 98% to 99% by mole), whereby a gas barrier layer forming liquid was prepared.

Composition of gas barrier layer forming liquid

| | | |
|---|---|---|
| Kuraray Exceval AQ-4105 (product name, | 3.7 | parts by mass |
| manufactured by KURARAY Co., Ltd.) | | |
| Polyethyleneimine (manufactured by | 0.3 | parts by mass |
| FUJIFILM Wako Pure Chemical Corporation, | | |
| average molecular weight: about 10,000) | | |
| Pure water | 88.5 | parts by mass |
| Isopropyl alcohol | 7.5 | parts by mass |

Subsequently, the obtained gas barrier layer forming liquid was filtered using a filter having an absolute filtration precision of 5 μm (product name: Hydrophobic Fluorepore Membrane, manufactured by Millex).

### (3) Lamination of Gas Barrier Layer

The gas barrier layer forming liquid after the filtration treatment was applied onto the corona-treated surface side of the base material 5 using a bar coater so that the film thickness after drying was 1.6 μm, and dried at 120° C. for 60 seconds to produce a light absorption filter No. 301 according to the embodiment of the present invention.

This light absorption filter has a configuration in which a base material 1, a wavelength selective absorption layer, and a gas barrier layer (an adjacent layer) are laminated in this order.

<3-3. Production of Light Absorption Filters Nos. c401 and r402>

A light absorption filter No. c401 for comparison was produced in the same manner as in the production of the light absorption filter No. 301, except that a change was made so that the polyethyleneimine in the gas barrier layer of the light absorption filter No. 301 was not blended.

Further, a light absorption filter No. r402 for reference was produced in the same manner as in the production of the light absorption filter No. c401, except that in the production of the light absorption filter No. c401, a change was made so that the coloring agent in the wavelength selective absorption layer No. 301 was not blended.

### [3-1. Light Resistance]

### (Production of Light Resistance Evaluation Film)

A triacetyl cellulose film (product name: Fujitac TG60UL, manufactured by FUJIFILM Corporation) having a thickness of 60 μm was bonded to the side of the gas barrier layer (adjacent layer) of the light absorption filter with a pressure sensitive adhesive 1 (product name: SK2057, manufactured by Soken Chemical & Engineering Co., Ltd.) having a thickness of about 20 μm being interposed. Subsequently, the base material 1 was peeled off, and glass was bonded to the wavelength selective absorption layer side to which the base material 1 was bonded with the pressure sensitive adhesive 1 (product name: SK2057, manufactured by Soken Chemical & Engineering Co., Ltd.) being interposed, whereby a light resistance evaluation film was produced.

The obtained light resistance evaluation film has a configuration in which the lamination is carried out in the following order; glass, a layer of the pressure-sensitive adhesive 1, the wavelength selective absorption layer, the gas barrier layer, a layer of the pressure-sensitive adhesive agent 1, and the triacetyl cellulose film.

### (Absorption Maximal Value of Light Resistance Evaluation Film)

Using a UV3600 spectrophotometer (product name) manufactured by Shimadzu Corporation, the absorbance of the light resistance evaluation film in a wavelength range of 200 to 1,000 nm was measured for every 1 nm. The absorbance difference between the absorbance of the light resistance evaluation film at each wavelength and the absorbance of the light resistance evaluation film having the same configuration except that it does not contain the coloring agent was calculated, and the maximum value of this absorbance difference was defined as the absorption maximal value.

It is noted that in the light resistance evaluation film of the light absorption filters Nos. 301 and c401, the absorbance difference was calculated by using the light resistance evaluation film of the light absorption filter No. r402, which does not contain the coloring agent.

### (Light Resistance)

The light resistance evaluation film was irradiated with light for 270 hours in an environment of 60° C. and 50% relative humidity with Super Xenon Weather Meter SX75 (product name) manufactured by Suga Test Instruments Co., Ltd., and each of the absorption maximal values before and after this irradiation was measured, and the light resistance was calculated according to the following expression. The results are shown in Table 4.

$$[ Light resistance ( \% ) ] = ( [ absorption maximal value after light irradiation for 270 hours ] \text{} / [ absorption maximal value before light irradiation ] ) \times 100$$

TABLE 4

| | | | Evaluation |
|---|---|---|---|
| | | | Light resistance |
| | Gas barrier layer | | Residual rate |
| | Basic compound | | after xenon |
| Light absorption | | Blending | irradiation for |
| filter No. | Kind | amount | 270 hours |
| 301 | Polyethyleneimine | 7.5 | 85% |
| c401 | Absent | Absent | 73% |

### (Note in Table)

The blending amount of the basic compound means a blending amount in terms of parts by mass with respect to 100 parts by mass of the gas barrier layer excluding the basic compound.

From the results in Table 4, it can be seen that the light absorption filter No. 301 according to the embodiment of the present invention, which contains polyethyleneimine as a basic compound in the gas barrier layer which is an adjacent layer of a wavelength selective absorption layer containing a coloring agent, has both excellent light resistance and excellent heat resistance as compared with the comparative light absorption filter No. c401 containing no polyethyleneimine.

Although the present invention has been described with reference to the embodiments, it is the intention of the inventors of the present invention that the present invention should not be limited by any of the details of the description unless otherwise specified and rather be construed broadly within the spirit and scope of the invention appended in WHAT IS CLAIMED IS.

### EXPLANATION OF REFERENCES

1: upper polarizing plate
2: direction of absorption axis of upper polarizing plate
3: liquid crystal cell upper electrode substrate
4: alignment control direction of upper substrate
5: liquid crystal layer
6: liquid crystal cell lower electrode substrate
7: alignment control direction of lower substrate
8: lower polarizing plate
9: direction of absorption axis of lower polarizing plate
B: backlight unit
10: liquid crystal display device

What is claimed is:

1. A light absorption filter comprising:
a wavelength selective absorption layer containing a resin and a squarine-based coloring agent represented by General Formula (1); and
an adjacent layer arranged on at least one surface of the wavelength selective absorption layer,
wherein the adjacent layer contains an acid or a basic compound, 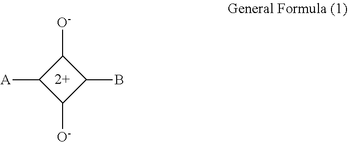
in the formula, A and B each independently represent an aryl group which may have a substituent, a heterocyclic group which may have a substituent, or —CH=G, where G represents a heterocyclic group which may have a substituent.

2. The light absorption filter according to claim 1,
wherein the wavelength selective absorption layer contains a compound A that has an acid group and a compound B that forms a hydrogen bond with the acid group contained in the compound A and generates a radical upon ultraviolet irradiation.

3. The light absorption filter according to claim 2,
wherein in the light absorption filter, the coloring agent is chemically changed to be decolorized upon ultraviolet irradiation.

4. An optical filter that is obtained by subjecting the light absorption filter according to claim 2 to mask exposure by ultraviolet irradiation.

5. An organic electroluminescent display device, an inorganic electroluminescent display device, or a liquid crystal display device, comprising:
the optical filter according to claim 4.

6. The organic electroluminescent display device, the inorganic electroluminescent display device, or the liquid crystal display device according to claim 5,
wherein a layer that inhibits light absorption of the compound B is provided on a viewer side with respect to the optical filter.

7. A manufacturing method for an optical filter, comprising:
irradiating the light absorption filter according to claim 2 with an ultraviolet ray to carry out mask exposure.
